(19) United States
(12) Patent Application Publication
(10) Pub. No.: US 2008/0054463 A1
(43) Pub. Date: Mar. 6, 2008

(54) Semiconductor apparatus and manufacturing method of semiconductor apparatus

(75) Inventor: Hiroyuki Nakanishi, Kizugawa-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka-shi (JP)

(21) Appl. No.: 11/882,374

(22) Filed: Aug. 1, 2007

(30) Foreign Application Priority Data
Aug. 29, 2006 (JP) 2006-232810

(51) Int. Cl. H01L 23/48; H01L 21/44

(52) U.S. Cl. 257/738; 438/614; 257/E23.01; 257/E21.476

(57) ABSTRACT

The semiconductor apparatus includes: a conductor section provided on a surface of a semiconductor chip so as to input and output an electric signal; and an external connection terminal provided on the surface of the conductor section so as to joint the conductor section to a package substrate, wherein the conductor section has a through hole provided on the surface of the conductor section and piercing a center of the surface of the conductor section, and the external connection terminal is formed along the through hole. As a result, it is possible to realize a semiconductor apparatus whose resistance against repetitive stresses and impulse is improved and which has high packaging reliability.

This Nonprovisional application claims priority under 35 U.S.C. § 119(a) on Patent Application No. 232810/2006 filed in Japan on Aug. 29, 2006, the entire contents of which are hereby incorporated by reference.

### FIELD OF THE INVENTION

The present invention relates to (i) a semiconductor apparatus including therein a semiconductor integrated circuit used for an electronic device such as an information communication device and (ii) a manufacturing method of the semiconductor apparatus.

### BACKGROUND OF THE INVENTION

Recently, in a field of an electronic device such as an information communication device and the like, an electronic part installed in a device has been required to have a smaller size and a higher function and to be packaged with higher density. Also, the electronic part has been required to be packaged with higher reliability. Further, also a package in which the electronic part is stored has been required to be packaged with higher reliability.

As a result, there was developed a semiconductor apparatus, generally referred to as “wafer level CSP (chip scale package)”, as a small-size package including a semiconductor chip therein.

The wafer level CSP is a surface-mounted package made smaller so as to have substantially the same size as a bare chip. An external connection terminal is provided on a package surface, and the external connection terminal on the package surface is connected to a package substrate, thereby realizing packaging. Therefore, an area occupied by the substrate can be made as small as the bare chip.

However, a solder ball is used as the external connection terminal, so that the semiconductor apparatus and the package substrate are connected by only the solder. Thus, if any crack occurs in the solder, the crack immediately expands, so that the solder is torn into upper and lower portions. That is, the external connection terminal is broken.

This raises a problem in improving the packaging reliability of a connection structure which allows connection of the semiconductor apparatus and the package substrate.

In order to improve the packaging reliability in particular, a structure in which a stress relief layer is provided below a conductor section connected to the external connection terminal is disclosed, for example, by Patent Document 1 (Japanese Patent No. 3335575 (Publication date: Feb. 26, 1999)) and Non Patent Document 1 (“Development of wafer process package including a stress relief function therein”, MES 2000 10th Microelectronics Symposium Memoirs, Japan Institute of Electronics Packaging (JIEP), 2000, p. 71 to 74)).

With reference to FIG. 29 and FIG. 30, the following describes a basic structure of a semiconductor apparatus 900a having a stress relief layer 905a provided below a conductor portion 904 connected to an external connection terminal 906 and a basic structure of a semiconductor apparatus 900b having a stress relief layer 905b provided below a conductor portion 904 connected to an external connection terminal 906.

FIG. 29 is a cross sectional view illustrating a structure in which stress relief layers 905a are respectively provided below external connection terminals 906 in the conventional semiconductor apparatus 900a.

FIG. 30 is a cross sectional view illustrating a structure in which a stress relief layer 905b is provided so as to extend along an area below external connection terminals 906 in the conventional semiconductor apparatus 900b.

As illustrated in FIG. 29, the semiconductor apparatus 900a includes a semiconductor chip 901 on which an electrode pad 902 for exchanging an electronic signal with the outside and receiving power from the outside is provided. Further, an insulation layer 903 is provided on the semiconductor chip 901 so as to cover a face on which the electrode pad 902 is formed. Note that, the insulation layer 903 is formed so that the electrode pad 902 is exposed.

Subsequently, the stress relief layer 905a is formed on the insulation layer 903. Further, a conductor section 904 is formed so as to cover the stress relief layer 905a. Above the conductor section 904, the external connection terminal 906 is provided.

Further, the conductor portion 904 is formed along the insulation layer 903 so as to be connected to the electrode pad 902. As a result, the electrode pad 902, the conductor portion 904, and the external connection terminal 906 are connected to one another, so that the semiconductor chip 901 can carry out electric exchange with the outside.

Further, the stress relief layer 905a is provided below each external connection terminal 906 so as to correspond to each external connection terminal 906.

Lastly, the insulation film 907 covers a surface of the conductor portion 904 so as to surround each external connection terminal 906.

According to this arrangement, the external connection terminal 906 causes the semiconductor chip 901 to function, and the insulation film 907 protects an element face of the semiconductor chip 901, and the stress relief layer 905a positioned below the external connection terminal 906 alleviates a stress exerted to the external connection terminal 906 after packaging onto the substrate.

As a basic structural difference from the semiconductor apparatus 900a, the semiconductor apparatus 900b includes the stress relief layer 905b instead of the stress relief layers 905a as illustrated in FIG. 30. The stress relief layer 905b is continuously formed along an area below the external connection terminals 906.

Also this arrangement has the same mechanism for improving the packaging reliability as that of the semiconductor apparatus 900a.

Generally, it is assumed that a device including therein a package substrate on which a semiconductor apparatus is packaged is used in various environments such as an environment whose temperature varies or an environment in which the device is roughly treated.

In case where the device is used in the environment whose temperature varies, parts constituting the semiconductor apparatus have thermal expansion coefficients different from each other, so that stresses are exerted onto the parts repetitively. Further, in case where the device is roughly used and falls down, an impact is exerted onto the semiconductor apparatus.

Thus, a crack locally occurs in a vicinity of a joint interface of the external connection terminal. Stresses are likely to be concentrated onto the joint interface.

In the conventional semiconductor apparatus, the stress relief layer is provided below the conductor section having the external connection terminal thereon, thereby alleviating the stresses exerted to the joint interface.

However, a shape of the interface between the external connection terminal and the conductor section does not change between the case where the stress relief layer is provided and the case where the stress relief layer is not provided.

Thus, in case where a crack occurs in the vicinity of the joint interface of the external connection terminal, if a force is exerted in a direction in which the external connection terminal and the conductor section are separated at the crack (crack expanding direction), even a weak force causes the crack to immediately expand inwardly from an outer edge since the joint interface is continuously formed without any gap.

As a result, the crack causes the contact section to be in such a breakage mode that the external connection terminal and the conductor section are directly separated from each other. That is, this raises such a problem that: if the crack occurs, the external connection terminal is immediately broken, which results in electric openness.

Thus, it is desired to realize higher reliability based on both resistance against repetitive stresses and resistance against an impulse.

Further, the stress relief layer causes the semiconductor apparatus to be totally thicker so that the increment of the thickness corresponds to the thickness of the stress relief layer. Thus, in case of a semiconductor apparatus required to have a smaller thickness and a smaller length, the foregoing arrangement results in disadvantage.

### SUMMARY OF THE INVENTION

The present invention was made in view of the foregoing problems, and an object of the present invention is to provide (i) a semiconductor apparatus whose resistance against repetitive stresses and impulse is improved and whose packaging reliability is higher and (ii) a manufacturing method of the semiconductor apparatus.

In order to solve the foregoing problems, a semiconductor apparatus of the present invention: a conductor section provided on a surface of a semiconductor chip so as to input and output an electric signal; and a joint terminal provided on the surface of the conductor section so as to joint the conductor section to a package substrate, wherein the conductor section has a level difference on its surface, and the joint terminal is provided along the level difference.

Further, a method according to the present invention for manufacturing a semiconductor apparatus including: a conductor section provided on a surface of a semiconductor chip so as to input and output an electric signal; and a joint terminal provided on the surface of the conductor section so as to joint the conductor section to a package substrate, said method comprising the steps of: forming a level difference on the surface of the conductor section; and forming the joint terminal along the level difference.

Generally, when a crack occurs in the joint terminal's outer edge in a vicinity of a joint interface due to repetitive stresses and an impulse, the continuous joint interface in a crack expanding direction allows the crack to immediately expand inwardly from the outer edge of the joint terminal.

However, according to the foregoing arrangement, the level difference is formed on the surface of the conductor section, and the joint terminal is formed along the level difference, so that the crack which immediately expands inwardly from the outer edge due to the continuous joint interface reaches the level difference while expanding.

At this time, in case where the level difference is made lower, formation of the joint terminal along the level difference causes the joint interface to have a gap in the crack expanding direction, so that a wall surrounding a material constituting the joint terminal appears.

While, also in case where the level difference is made upper, the joint interface has a gap in the crack expanding direction, so that a wall surrounding a material constituting the level difference appears.

A force for generating a crack in a portion except for the joint interface of the joint terminal is stronger than a force for expanding the crack in the vicinity of the joint interface. Thus, when the crack reaches the level difference, expansion of the crack stops in the vicinity of the outer edge of the level difference.

As a result, connection of the joint terminal is secured, so that this does not result in immediate electric openness. That is, it is possible to extend a time period from occurrence of the crack to complete breakage of the joint terminal.

Therefore, it is possible to enhance the resistance against the repetitive stresses and the impulse. Therefore, it is possible to prevent immediate breakage of the joint terminal, thereby improving the packaging reliability.

In this manner, the semiconductor apparatus of the present invention allows enhancement of the resistance against the repetitive stresses and the impulse and realizes higher packaging reliability. Further, the level difference is formed on the surface of the conductor section positioned inside the joint terminal, so that it is possible to exert the foregoing effect without having any influence on appearance of the semiconductor apparatus. Furthermore, it is not necessary to provide a conventional stress relief layer, so that it is possible to reduce the number of parts.

Further, the method according to the present invention for manufacturing the semiconductor apparatus allows enhancement of the resistance against the repetitive stresses and the impulse and realizes higher packaging reliability. Further, the level difference is formed on the surface of the conductor section positioned inside the joint terminal, so that it is possible to manufacture the semiconductor apparatus which can exert the foregoing effect without having any influence on appearance of the semiconductor apparatus.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a cross sectional view illustrating one embodiment of a semiconductor apparatus of the present invention so as to show a state in which the semiconductor apparatus is cross-sectioned along a cross section S1 illustrated in FIG. 2.

FIG. 2 is an oblique view illustrating an arrangement of the semiconductor apparatus.

FIG. 3 is a cross sectional view illustrating an arrangement of the semiconductor apparatus packaged on a substrate.

FIG. 4 is a cross sectional view illustrating the semiconductor apparatus having an insulation film so as to show a state in which the semiconductor apparatus is cross-sectioned along a cross section S2 illustrated in FIG. 5.

FIG. 5 is an oblique view illustrating an arrangement of the semiconductor apparatus.

FIG. 6 is a cross sectional view illustrating the semiconductor apparatus having a conductor section of another arrangement so as to show a state in which the semiconductor apparatus is cross-sectioned along a cross section S3 illustrated in FIG. 7.

FIG. 7 is an oblique view illustrating an arrangement of the semiconductor apparatus.

FIG. 8 is a cross sectional view illustrating another embodiment of the semiconductor apparatus of the present invention so as to show a state in which the semiconductor apparatus is cross-sectioned along a cross section S4 illustrated in FIG. 9.

FIG. 9 is an oblique view illustrating an arrangement of the semiconductor apparatus.

FIG. 10 is a cross sectional view illustrating an arrangement of the semiconductor apparatus packaged on a substrate.

FIG. 11 is a cross sectional view illustrating the semiconductor apparatus having an insulation film so as to show a state in which the semiconductor apparatus is cross-sectioned along a cross section S5 illustrated in FIG. 12.

FIG. 12 is an oblique view illustrating an arrangement of the semiconductor apparatus.

FIG. 13 is a cross sectional view illustrating still another embodiment of the semiconductor apparatus of the present invention so as to show a state in which the semiconductor apparatus is cross-sectioned along a cross section S6 illustrated in FIG. 14.

FIG. 14 is an oblique view illustrating an arrangement of the semiconductor apparatus.

FIG. 15 is a cross sectional view illustrating the semiconductor apparatus having an insulation film so as to show a state in which the semiconductor apparatus is cross-sectioned along a cross section S7 illustrated in FIG. 16.

FIG. 16 is an oblique view illustrating an arrangement of the semiconductor apparatus.

FIG. 17 is a cross sectional view illustrating further still another embodiment of the semiconductor apparatus of the present invention so as to show a state in which the semiconductor apparatus is cross-sectioned along a cross section S8 illustrated in FIG. 18.

FIG. 18 is an oblique view illustrating an arrangement of the semiconductor apparatus.

FIG. 19 is a cross sectional view illustrating the semiconductor apparatus having an insulation film so as to show a state in which the semiconductor apparatus is cross-sectioned along a cross section S9 illustrated in FIG. 20.

FIG. 20 is an oblique view illustrating an arrangement of the semiconductor apparatus.

FIG. 21(a) to FIG. 21(f) are diagrams each of which illustrates a step in manufacturing the semiconductor apparatus illustrated in FIG. 1.

FIG. 22(a) to FIG. 22(h) are diagrams each of which illustrates a step in manufacturing the semiconductor apparatus illustrated in FIG. 8.

FIG. 23(a) to FIG. 23(h) are diagrams each of which illustrates a step in manufacturing the semiconductor apparatus illustrated in FIG. 11.

FIG. 24(a) to FIG. 24(h) are diagrams each of which illustrates a step in manufacturing the semiconductor apparatus illustrated in FIG. 13.

FIG. 25(a) to FIG. 25(i) are diagrams each of which illustrates a step in manufacturing the semiconductor apparatus illustrated in FIG. 17.

FIG. 26 is a cross sectional view illustrating an arrangement of a conventional semiconductor apparatus.

FIG. 27 is a cross sectional view illustrating further still another embodiment of the semiconductor apparatus of the present invention.

FIG. 28 is an oblique view illustrating an arrangement of the semiconductor apparatus.

FIG. 29 is a cross sectional view illustrating an arrangement of a conventional semiconductor apparatus.

FIG. 30 is a cross sectional view illustrating another arrangement of the conventional semiconductor apparatus.

### DESCRIPTION OF THE EMBODIMENTS

### Embodiment 1

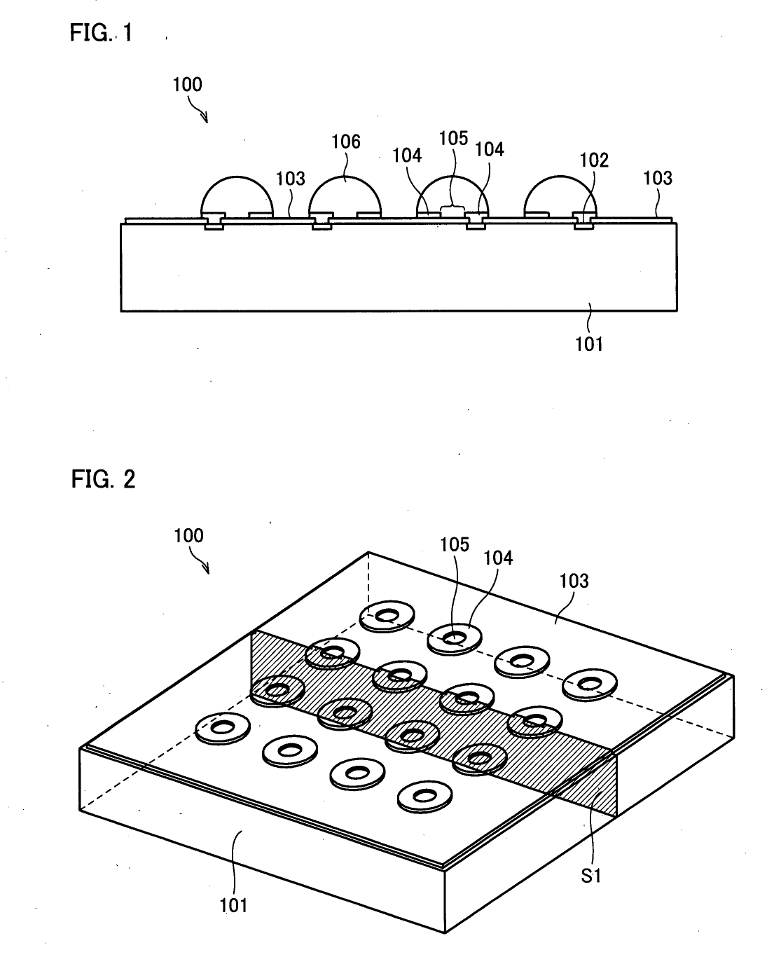

The following description explains one embodiment of the present invention with reference to FIG. 1 to FIG. 7.

First, an arrangement of a semiconductor apparatus 100 of the present embodiment is described as follows with reference to FIG. 1 and FIG. 2.

FIG. 1 is a cross sectional view of the semiconductor apparatus 100 in case where the semiconductor apparatus 100 is cross-sectioned along a cross section S1 illustrated in FIG. 2.

FIG. 2 is an oblique view illustrating an arrangement of the semiconductor apparatus 100. Note that, external connection terminals 106 are not illustrated in order to clearly illustrate shapes of conductor sections 104.

Also, continuous lines and dotted lines of FIG. 1 and FIG. 2 do not necessarily exactly illustrate the actual state and are used for convenience in description. Hereinafter, this is the same also in other drawings.

As illustrated in FIG. 1, the semiconductor apparatus 100 of the present embodiment includes a semiconductor chip 101, electrode pads 102, an insulation layer 103, conductor sections 104, and external connection terminals 106 (joint terminals). This is a surface-mounted package of a wafer level CSP.

The semiconductor chip 101 has a plate shape. On the semiconductor chip 101, a semiconductor device corresponding to a function of the semiconductor apparatus 100 is packaged.

Each of the electrode pads 102 serves as an inlet/outlet via which an electric signal is inputted from the outside to the semiconductor chip 101, an electric signal is outputted from the semiconductor chip 101 to the outside, and power is supplied from the outside into the semiconductor chip 101.

Further, a surface of the electrode pad 102 is made of aluminum (Al) or aluminum alloy, and 4×4 electrode pads 102 are provided on a side of the semiconductor chip 102 in a matrix manner. However, positions and the number of the electrode pads 102 to be formed are not limited to this and may be suitably set according to a size of the semiconductor apparatus 100 and the number of electric signal input/output pins. Herein, the side where the electrode pads 102 are formed is referred to as a main side (side where elements are formed).

The insulation layer 103 allows the electrode pads 102 to be insulated from each other and covers the main side of the semiconductor chip 101 so that the electrode pads 102 are exposed.

Further, the insulation layer 103 is constituted of a film made of silicon dioxide (SiO₂) or silicon nitride (SiN). Further, a polymer material such as polyimide, polybenzoxazole (PBO), and benzocyclobutene (BCB) may be formed on the film so as to have the thickness about 3 to 10 μm.

Each of the conductor sections 104 has a flat and substantially cylindrical shape and has a through hole 105 (level difference) formed so as to pierce a center of a surface of the conductor section 104. Further, the conductor section 104 is formed by plating and pierces the insulation layer 103 so as to be in contact with the electrode pad 102. 4×4 of the conductor sections 104 are disposed in a matrix manner. However, positions and the number of the conductor sections 104 are not limited to this and may be suitably set according to a size of the semiconductor apparatus 100 and the number of the electrode pads 102.

Further, the conductor section 104 is made mainly of copper (Cu) whose thickness is about 10 μm. However, a copper (Cu) thin film (thickness is about 0.1 μm) serving as a seed layer is formed on a lower side (side in contact with the electrode pad 102) of the conductor section 104 by sputtering. Further, in order to suppress mutual diffusion of aluminum (Al) and copper (Cu) of the electrode pad 102, a titanium (Ti), titanium tungsten (TiW), or chromium (Cr) thin film (thickness is about 0.1 μm) is formed on a lower side of the thin film by sputtering.

It is preferable that a diameter of the through hole 105 is ⅓ to ⅔ of a diameter of the conductor section 104. In the present embodiment, in case where a pitch of the external connection terminals 106 is 0.5 mm for example, the diameter of the conductor section 104 is 0.27 mm and the diameter of the cyclic through hole 105 is 0.09 to 0.18 mm.

Note that, at the through hole 105, the insulation layer 103 is exposed unless the external connection terminal 106 is formed.

The external connection terminal 106 is a solder ball constituted of solder made mainly of tin (Sn). Further, the solder is melted so as to connect the external connection terminal 106 to the package substrate for example.

Further, the external connection terminal 106 is formed above the conductor section 104 so as to be in contact with the conductor section 104 by filling the through hole 105 of the conductor section 104 with solder. In case of the present embodiment, if the external connection terminals 106 are formed by printing, a height thereof ranges from 0.12 to 0.2 mm (inclusive of unevenness) and a height in installing solder balls thereon ranges from 0.18 to 0.27 mm. Note that, the heights are not limited to them if an amount of solder is intentionally increased. In this case, also the diameter is larger than the diameter of the conductor section 104. However, excessive increase of the solder is highly likely to cause the external connection terminals to be connected (bridged) to one another at the time of packaging on the substrate.

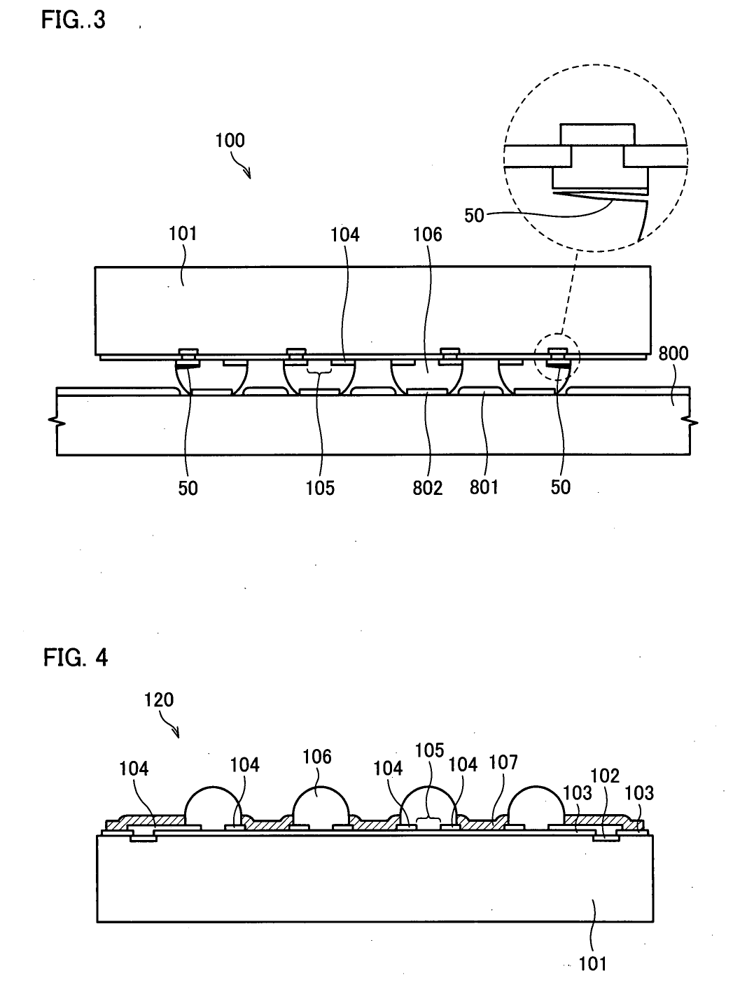

Next, with reference to FIG. 3, the following describes how a crack 50 acts on the external connection terminal 106 in packaging the semiconductor apparatus 100 onto a package substrate 800.

FIG. 3 is a cross sectional view illustrating the semiconductor apparatus 100 and the package substrate 100 in case where the crack 50 occurs in the external connection terminal 106.

On a package surface of the package substrate 800, solder resists 801 covering a surface of the substrate and metals 802 serving as packaging sections of the substrate are formed. Note that, illustrations of other packaging parts are omitted.

The metals 802 are disposed in the same manner as the external connection terminals 106 of the semiconductor apparatus 100. Further, each of the metals 802 of the package substrate 800 and each of the external connection terminals 106 are bonded to each other, thereby packaging the semiconductor apparatus 100 onto the package substrate 800. As a result, electrical connection between the semiconductor apparatus 100 and the package substrate 800 is realized.

Further, the package substrate 800 on which the semiconductor apparatus 100 has been packaged is stored in a housing (not shown) of an electric device or the like for example.

Generally, it is assumed that the device is used in various environments such as an environment whose temperature is high or an environment in which the device is roughly treated.

In case where the device is used in the environment whose temperature is high, parts constituting the semiconductor apparatus 100 have thermal expansion coefficients different from each other, so that stresses are exerted onto the parts repetitively. Further, in case where the device is roughly used and falls down, an impact is exerted onto the semiconductor apparatus 100.

Thus, the crack 50 locally occurs in a vicinity of a joint interface of the external connection terminal 106. Stresses are likely to be concentrated onto the joint interface. Note that, the vicinity of the joint interface of the external connection terminal 106 refers to (i) a vicinity of a joint on the side of the semiconductor apparatus 100 and (ii) a vicinity of a joint on the side of the package substrate 800. A weaker one of the vicinities is first broken depending on a shape difference and a size difference between the joints.

Note that, the present invention is to improve the packaging reliability in solving the problem caused by the crack 50 which occurs in the vicinity of the joint of the external connection terminal 106 which joint is positioned on the side of the semiconductor apparatus 100 (the crack 50 which occurs in (i) an Sn—Cu alloy layer generated in a vicinity of the joint interface of the external connection terminal 106 by formation of the external connection terminal 106 directly above the conductor section 104 or in (ii) a solder portion in a vicinity thereof). Hereinafter, the vicinity of the joint interface of the external connection terminal 106 means the vicinity of the joint on the side of the semiconductor apparatus 100.

At this time, in the semiconductor apparatus 100 packaged on the package substrate 800, only the external connection terminal 106 serves as a joint portion, so that only the external connection terminal 106 supports the semiconductor apparatus 100.

Thus, in case where the crack 50 occurs in the vicinity of the joint interface of the external connection terminal 106, when a force is exerted in a direction in which the external connection terminal 106 and the conductor section 104 are separated from each other (in a direction in which the crack 50 expands), the continuous joint interface having no gap allows the crack 50 to immediately expand inwardly from the outer edge even with a weak force.

As a result, the crack 50 causes the joint portion to be in a breakage mode in which the external connection terminal 106 and the conductor section 104 are directly separated from each other in a vertical direction. That is, the crack 50 causes the external connection terminal 106 to be immediately broken, which results in electric openness.

However, the conductor section 104 has the through hole 105, so that the crack 50 reaches the through hole 105, which is relatively large, while expanding. At this time, the joint interface has a gap in the direction in which the crack 50 expands, so that a wall filled with a material constituting the external connection terminal 106 appears.

A force for generating the crack 50 in a portion other than the joint interface of the external connection terminal 106 is stronger than the force for expanding the crack 50 in the vicinity of the joint interface. Thus, when the crack 50 reaches the through hole 105 filled with the external connection terminal 106, expansion of the crack 50 stops in a vicinity of an outer edge of the through hole 105 of the conductor section 104. Further, the cut portion is freely movable in a horizontal direction to some extent, so that the cut portion is resistive against a slight force.

Thus, connection of the external connection terminal 106 is secured, so that this does not result in immediate electric openness. That is, it is possible to extend a time period from occurrence of the crack 50 to complete breakage of the external connection terminal 106.

Further, the solder constituting the external connection terminal 106 is provided also on an outer edge internally positioned in the through hole 105 of the conductor section 104. Thus, an anchor effect thereof improves the connection strength.

In this manner, the semiconductor apparatus 100 of the present embodiment is arranged so as to include: the conductor section 104 provided on a surface of the semiconductor chip 101 so as to input and output an electric signal; and the external connection terminal 106 provided on the surface of the conductor section 104 so as to joint the conductor section 104 to the package substrate 800, wherein the through hole 105 is formed on the surface of the conductor section 104 so as to pierce a center of the surface of the conductor section 104, and the external connection terminal 106 is formed along the through hole 105.

Generally, when the crack 50 occurs in the external connection terminal 106's outer edge in the vicinity of the joint interface due to the repetitive stresses and the impulse, the continuous joint interface in the direction in which the crack 50 expands allows the crack 50 to immediately expand inwardly from the outer edge of the external connection terminal 106.

However, according to the foregoing arrangement, the though hole 105 is formed on the surface of the conductor section 104 so as to pierce the center of the surface of the conductor section 104 and the external connection terminal 106 is formed along the through hole 105, so that the crack 50 which immediately expands inwardly from the outer edge due to the continuous joint interface reaches the through hole 105 while expanding. At this time, the joint interface has a gap in the direction in which the crack 50 expands, so that the wall filled with the material constituting the external connection terminal 106 appears.

A force for generating the crack 50 in a portion other than the joint interface of the external connection terminal 106 is stronger than the force for expanding the crack 50 in the vicinity of the joint interface. Thus, when the crack 50 reaches the through hole 105 filled with the external connection terminal 106, expansion of the crack 50 stops in the vicinity of the outer edge of the through hole 105.

Thus, connection of the external connection terminal 106 is secured, which does not result in immediate electric openness. That is, it is possible to extend a time period from occurrence of the crack 50 to complete breakage of the external connection terminal 106.

Thus, it is possible to enhance the resistance against the repetitive stresses and the impulse. Therefore, it is possible to prevent immediate breakage of the external connection terminal 106, thereby improving the packaging reliability.

In this manner, the semiconductor apparatus 100 of the present embodiment allows enhancement of the resistance against the repetitive stresses and the impulse and realizes higher packaging reliability.

Further, the through hole 105 is formed on the surface of the conductor section 104 positioned inside the external connection terminal 106, so that it is possible to exert the foregoing effect without having any influence on appearance of the semiconductor apparatus 100. Furthermore, it is not necessary to provide a conventional stress relief layer, so that it is possible to reduce the number of parts.

Incidentally, the foregoing arrangement of the semiconductor apparatus 100 is applicable to the case where there is the external connection terminal 106 above the electrode pad 102. However, the semiconductor chip 101 may be stored in another semiconductor apparatus to be wire-bonded. In this case, it is often that the electrode pad 102 is disposed in a vicinity of an outer edge of the semiconductor chip 101.

Thus, in case of packaging the semiconductor chip 101 as a surface-mounted package, it is necessary to extend the conductor section 104 in order to connect the external connection terminal 106 and the electrode pad 102 to each other. However, when a portion other than a region where the external connection terminal 106 is to be provided is exposed by extending the conductor section 104, not only corrosion of the portion but also current leak occur.

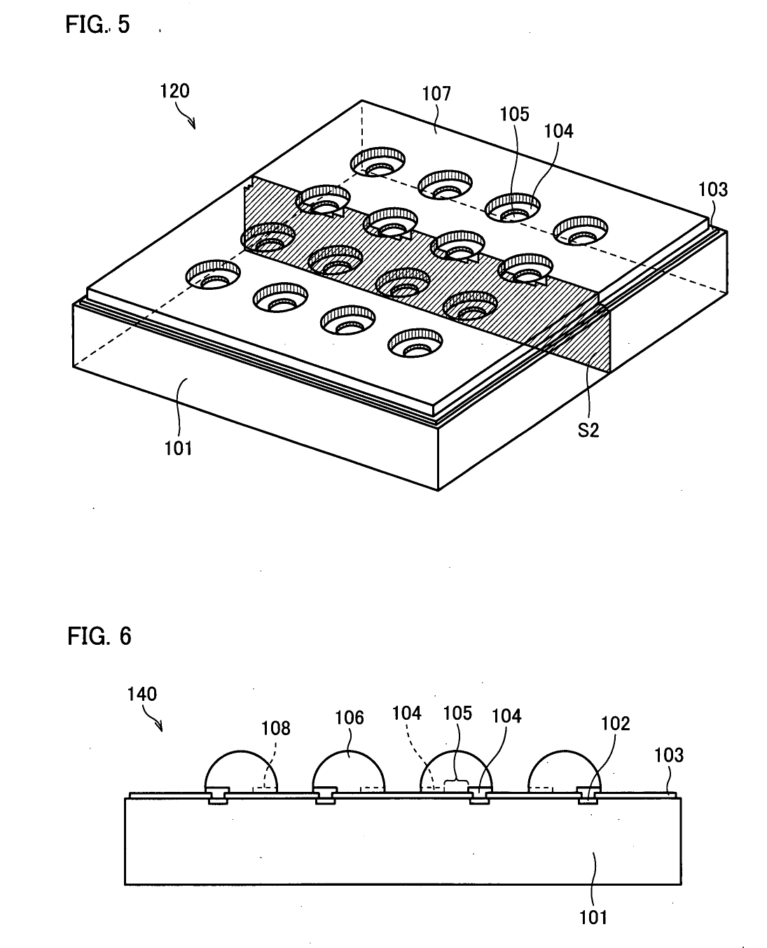

With reference to FIG. 4 and FIG. 5, the following describes an arrangement in which: (i) a side face of the conductor section 104 on which the external connection terminal 106 is provided and (ii) an outline of a top face of the conductor section 104 are coated with an insulation film 107.

FIG. 4 is a cross sectional view of a cross section S2 of a semiconductor apparatus 120 illustrated in FIG. 5.

FIG. 5 is an oblique view illustrating an arrangement of the semiconductor apparatus 120 including the insulation film 107. Note that, the external connection terminal 106 is not illustrated in order to clarify a shape of the conductor section 104.

In addition to the arrangement of the semiconductor apparatus 100, the semiconductor apparatus 120 includes the insulation film 107. However, as illustrated in FIG. 4, the electrode pad 102 is disposed in the vicinity of the outer edge of the semiconductor chip 101.

The conductor section 104 is formed so as to connect the external connection terminal 106 and the electrode pad 102 to each other. Therefore, even if the electrode pad 102 is disposed in the vicinity of the outer edge of the semiconductor chip 101 and is not positioned below the external connection terminal 106, it is possible to connect the electrode pad 102 and the external connection terminal 106 to each other by extending the conductor section 104.

The insulation film 107 covers not only the conductor section 104 extended as a wiring but also a periphery of the external connection terminal 106. Further, a size of the conductor section 104 is larger than the aforementioned size so that the increment corresponds to an amount of the insulation film 107 with which the outline of the top face of the conductor section 104 provided on the external connection terminal 106 is coated. For example, if the amount of the insulation film 107 with which the outline is coated is 0.015 mm, a diameter of the conductor section 104 is set to 0.3 mm.

As a result, even if the electrode pad 102 is disposed in the vicinity of the outer edge of the semiconductor chip 101 and the conductor section 104 is extended and exposed so as to connect the external connection terminal 106 and the electrode pad 102 to each other, the exposed portion of the conductor section 104 is covered by the insulation film 107, so that it is possible to prevent corrosion of the exposed portion and occurrence of current leak.

Further, in providing the external connection terminal 106 on the conductor section 104, the external connection terminal 106 is formed while melting the solder constituting the external connection terminal 106. At this time, air is included in the solder, so that this may result in occurrence of voids in the external connection terminal 106. The void decreases the packaging reliability, so that it is not preferable that there is any void.

Thus, it is possible to reduce the voids by providing a groove 108, extending from the through hole 105 in the center of the conductor section 104 to the outer edge of the conductor section 104, on the conductor section 104 provided on the external connection terminal 106.

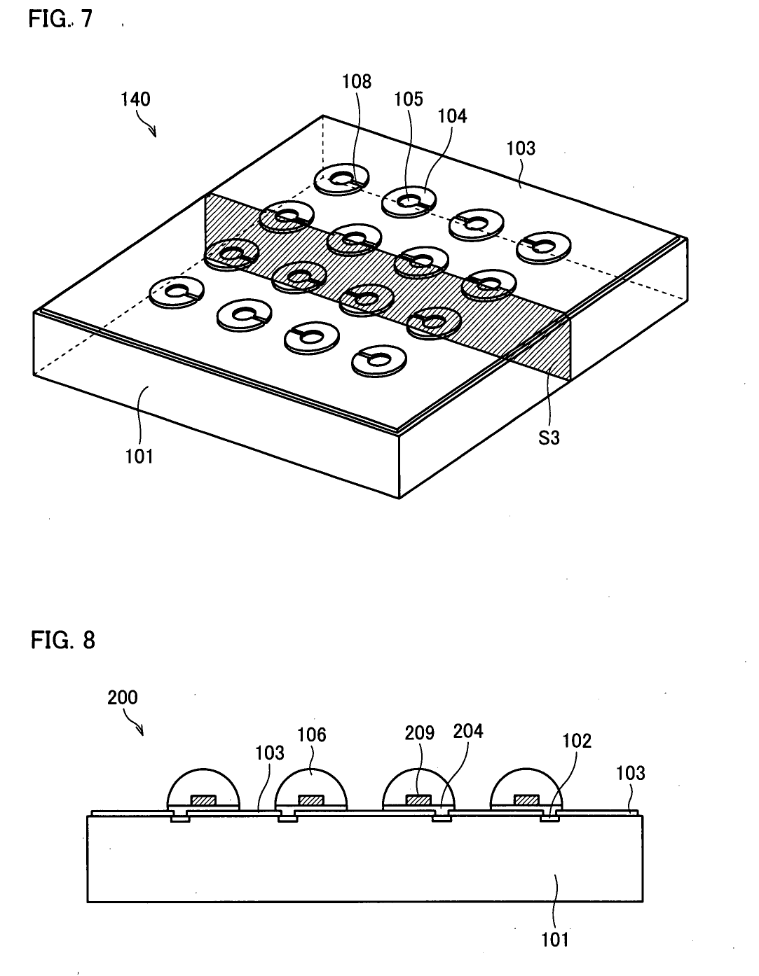

With reference to FIG. 6 and FIG. 7, the following describes a semiconductor apparatus 140 including the groove 108 provided on the conductor section 104.

FIG. 6 is a cross sectional view taken along a cross section S3 of the semiconductor apparatus 140 illustrated in FIG. 7.

FIG. 7 is an oblique view illustrating an arrangement of the semiconductor apparatus 140 including the conductor section 104 having the groove 108. Note that, the external connection terminal 106 is not illustrated in order to clarify a shape of the conductor section 104.

In addition to the arrangement of the semiconductor apparatus 100, the semiconductor apparatus 140 includes the groove 108 provided on the conductor section 104.

The groove 108 is formed so as to extend from the through hole 105 in the center of the conductor section 104 to the outer edge of the conductor section 104. Therefore, the surface of the conductor section 104 has not an O-shape but a C-shape.

As a result, in melting the solder constituting the external connection terminal 106 so as to provide the external connection terminal 106 on the conductor section 104, the groove 108 allows reduction of air included and kept in the solder. Thus, it is possible to finally suppress presence of voids in the external connection terminal 106 and improve the packaging reliability.

### Embodiment 2

With reference to FIG. 8 to FIG. 12, the following describes another embodiment of the present invention. Note that, the present embodiment is arranged in the same manner as in Embodiment 1 except for points described below. Further, for convenience in descriptions, the same reference numerals are given to members having the same functions as the members illustrated in the drawings of Embodiment 1, and descriptions thereof are omitted.

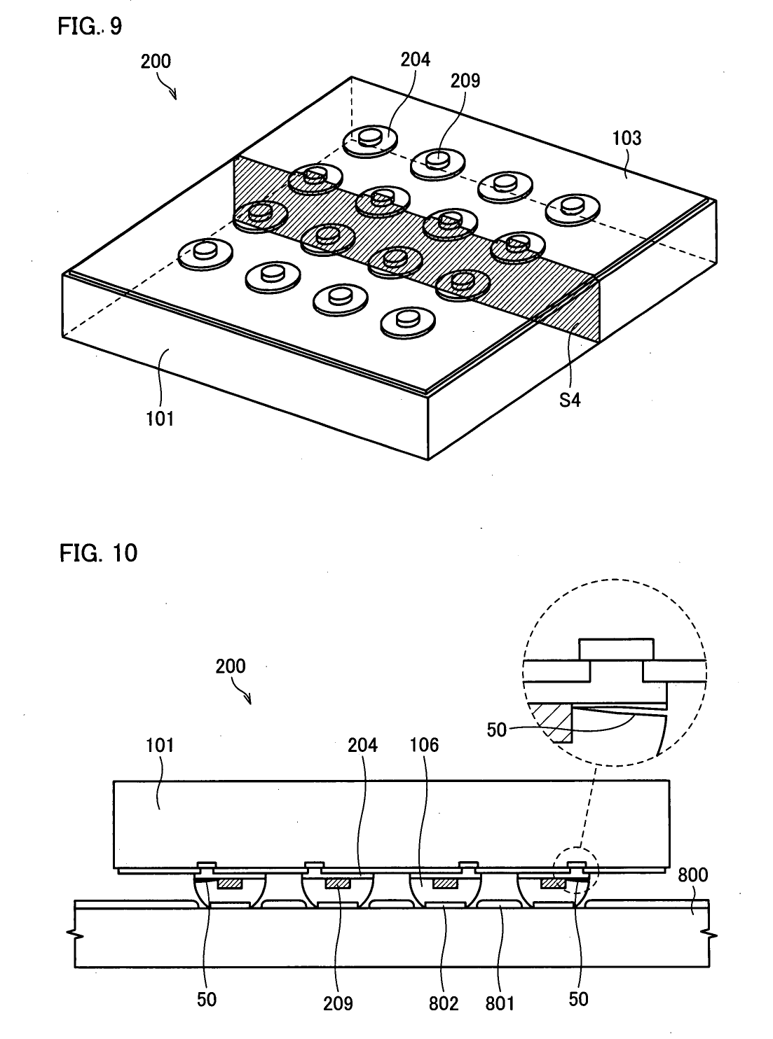

First, an arrangement of a semiconductor apparatus 200 of the present embodiment is described as follows with reference to FIG. 8 and FIG. 9.

FIG. 8 is a cross sectional view taken along a cross section S4 of the semiconductor apparatus 200 illustrated in FIG. 9.

FIG. 9 is an oblique view illustrating the arrangement of the semiconductor apparatus 200. Note that, the external connection terminal 106 is not illustrated in order to clarify shapes of a conductor section 204 and a protrusion 209.

As illustrated in FIG. 8, in addition to the arrangement of the semiconductor apparatus 100 of Embodiment 1, the semiconductor apparatus 200 of the present embodiment includes the conductor section 204 and the protrusion 209 (level difference) instead of the conductor section 104 having the through hole 105.

The conductor section 204 is arranged by removing the through hole 105 from the conductor section 104.

The protrusion 209 has a flat and substantially cylindrical shape and is provided on a center of a surface of the conductor section 204 so as to be positioned inside the external connection terminal 106. That is, the protrusion 209 is formed on a face, at which the external connection terminal 106 and the conductor section 204 are in contact with each other, so as to be covered by the external connection terminal 106.

Further, the protrusion 209 is made of polymer material such as polyimide, polybenzoxazole (PBO), and benzocyclobutene (BCB), and is formed by photolithography or screen printing.

It is preferable that a diameter of the protrusion 209 is ⅓ to ⅔ of a diameter of the conductor section 204. In the present embodiment, in case where a pitch of the external connection terminals 106 is 0.5 mm for example, the diameter of the conductor section 204 is 0.27 mm and the diameter of the protrusion 209 is 0.09 to 0.18 mm.

Next, with reference to FIG. 10, the following describes how the crack 50 acts on the external connection terminal 106 in packaging the semiconductor apparatus 200 onto the package substrate 800.

FIG. 10 is a cross sectional view illustrating the semiconductor apparatus 200 and the package substrate 800 in case where the crack 50 occurs in the external connection terminal 106.

The semiconductor apparatus 200 is packaged on the package substrate 800 by connecting metals 802 of the package substrate 800 to the external connection terminals 106 of the semiconductor apparatus 200.

In case where the crack 50 occurs in the external connection terminal 106 due to the repetitive stresses and impact, if a force is exerted in a direction in which the external connection terminal 106 and the conductor section 204 are separated at the crack 50 (a direction in which the crack 50 expands), even a weak force causes the crack 50 to immediately expand inwardly from an outer edge since the joint interface is continuously formed without any gap.

As a result, the crack 50 causes the joint portion to be in a breakage mode in which the external connection terminal 106 and the conductor section 204 are directly separated from each other in a vertical direction. That is, the crack 50 causes the external connection terminal 106 to be immediately broken, which results in electric openness.

However, the protrusion 209 is formed on the conductor section 204, so that the crack 50 reaches the protrusion 209 while expanding. At this time, the joint interface has a gap in the direction in which the crack 50 expands, so that a wall of the protrusion 209 appears.

Thus, when the crack 50 reaches the protrusion 209, presence of an inflectional portion referred to as the protrusion 209 causes the stress to be alleviated, so that expansion of the crack 50 stops in the vicinity of the outer edge. Further, the cut portion is freely movable in a horizontal direction to some extent, so that the cut portion is resistive against a slight force.

Thus, connection of the protrusion 209 and the external connection terminal 106 is secured, so that this does not result in immediate electric openness. That is, it is possible to extend a time period from occurrence of the crack 50 to complete breakage of the external connection terminal 106.

Further, the protrusion 209 is made of the polymer material which is more likely to be deformed than the solder, so that the protrusion 209 itself alleviates the stress exerted to the external connection terminal 106, thereby further enhancing the resistance particularly against the repetitive stresses. As a result, it is possible to improve the packaging reliability.

In this manner, the semiconductor apparatus 200 of the present embodiment is arranged so as to include: the conductor section 204 provided on the surface of the semiconductor chip 101 so as to input and output an electric signal; and the external connection terminal 106 provided on the surface of the conductor section 204 so as to joint the conductor section 204 to the package substrate 800, wherein the conductor section 204 has the protrusion 209 which is formed in a flat and substantially cylindrical shape on the center of the surface of the conductor section 204 so as to be covered by the external connection terminal 106, and the external connection terminal 106 is formed along the protrusion 209.

Generally, when the crack 50 occurs in the external connection terminal 106's outer edge in the vicinity of the joint interface due to the repetitive stresses and the impulse, the continuous joint interface in the direction in which the crack 50 expands allows the crack 50 to immediately expand inwardly from the outer edge of the external connection terminal 106.

However, according to the foregoing arrangement, the protrusion 209 is formed in a flat and substantially cylindrical shape on the center of the surface of the conductor section 204 so as to be covered by the external connection terminal 106, and the external connection terminal 106 is formed along the protrusion 209, so that the crack 50 which immediately expands inwardly from the outer edge due to the continuous joint interface reaches the protrusion 209 while expanding. At this time, the joint interface has a gap in the direction in which the crack 50 expands, so that the wall of the protrusion 209 appears.

Thus, when the crack 50 reaches the protrusion 209, presence of an inflectional portion referred to as the protrusion 209 causes the stress to be alleviated, so that expansion of the crack 50 stops in the vicinity of the outer edge.

As a result, connection of the protrusion 209 and the external connection terminal 106 is secured, which does not result in immediate electric openness. That is, it is possible to extend a time period from occurrence of the crack 50 to complete breakage of the external connection terminal 106.

Thus, it is possible to enhance the resistance against the repetitive stresses and the impulse. Therefore, it is possible to prevent immediate breakage of the external connection terminal 106, thereby improving the packaging reliability.

In this manner, the semiconductor apparatus 200 of the present embodiment allows enhancement of the resistance against the repetitive stresses and the impulse and realizes higher packaging reliability.

Further, the protrusion 209 is made of the polymer material which is more likely to be deformed than the solder, so that the protrusion 209 itself alleviates the stress exerted to the external connection terminal 106, thereby further enhancing the resistance particularly against the repetitive stresses. As a result, it is possible to improve the packaging reliability.

Further, the protrusion 209 is formed on the surface of the conductor section 204 positioned inside the external connection terminal 106, so that it is possible to exert the foregoing effect without having any influence on appearance of the semiconductor apparatus 200.

Also in the semiconductor apparatus 200, the semiconductor chip 101 may be stored in another semiconductor apparatus to be wire-bonded. In this case, it is often that the electrode pad 102 is disposed in a vicinity of an outer edge of the semiconductor chip 101.

Thus, in case of packaging the semiconductor chip 101 as a surface-mounted package, it is necessary to extend the conductor section 204 in order to connect the external connection terminal 106 and the electrode pad 102 to each other as in Embodiment 1. However, when a portion other than a region where the external connection terminal 106 is to be formed is exposed by extending the conductor section 204, not only corrosion of the portion but also current leak occur.

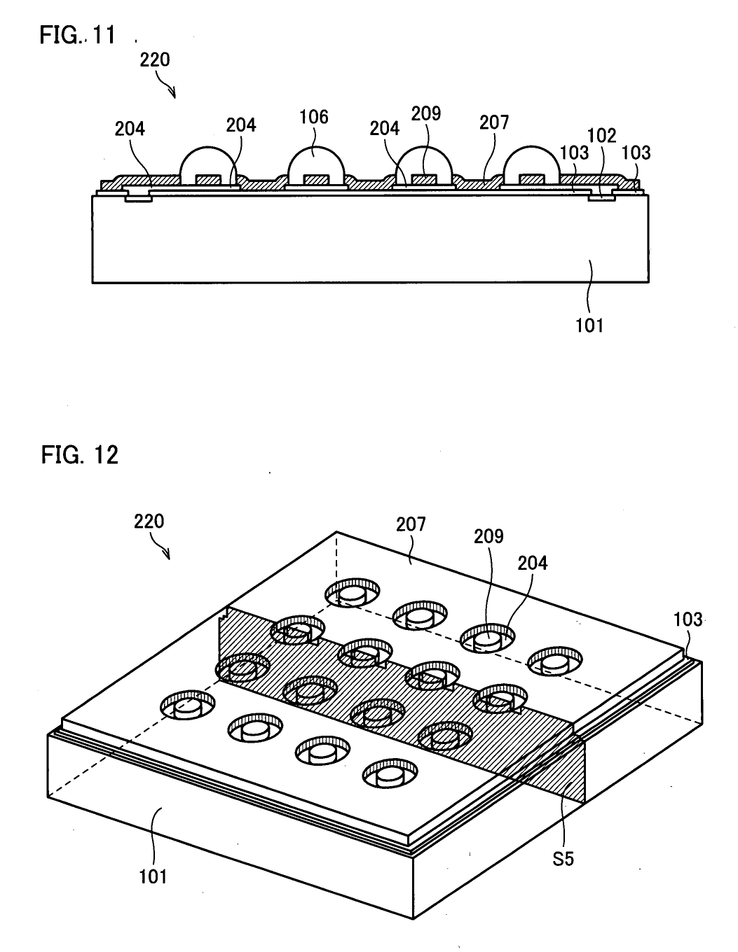

With reference to FIG. 11 and FIG. 12, the following describes an arrangement in which a side face of the conductor section 204 having the external connection terminal 106 thereon and an outline of a top face of the conductor section 204 are coated with an insulation film 207.

FIG. 11 is a cross sectional view taken along a cross section S5 of a semiconductor apparatus 220 illustrated in FIG. 12.

FIG. 12 is an oblique view illustrating an arrangement of the semiconductor apparatus 220 including the insulation film 207. Note that, the external connection terminal 106 is not illustrated in order to clarify shapes of the conductor section 204 and the protrusion 209.

In addition to the arrangement of the semiconductor apparatus 200, the semiconductor apparatus 220 includes the insulation film 207. However, as illustrated in FIG. 11, the electrode pad 102 is disposed in the vicinity of the outer edge of the semiconductor chip 101.

The conductor section 204 is formed so as to connect the external connection terminal 106 and the electrode pad 102 to each other. Therefore, even if the electrode pad 102 is disposed in the vicinity of the outer edge of the semiconductor chip 101 and is not positioned below the external connection terminal 106, it is possible to connect the electrode pad 102 and the external connection terminal 106 to each other by extending the conductor section 204.

The insulation film 207 covers not only the conductor section 204 extended as a wiring but also a periphery of the external connection terminal 106. Further, a size of the conductor section 204 is larger than the aforementioned size so that the increment corresponds to an amount of the insulation film 207 with which the outline of the top face of the conductor section 204 provided on the external connection terminal 106 is coated. For example, if the amount of the insulation film 207 with which the outline is coated is 0.015 mm, a diameter of the conductor section 204 is set to 0.3 mm.

As a result, even if the electrode pad 102 is disposed in the vicinity of the outer edge of the semiconductor chip 101 and the conductor section 204 is extended and exposed so as to connect the external connection terminal 106 and the electrode pad 102 to each other, the exposed portion of the conductor section 204 is covered by the insulation film 207, so that it is possible to prevent corrosion of the exposed portion and occurrence of current leak.

Note that, the insulation film 207 is formed in the same step and at the same time as in the protrusion 209. This will be detailed in a below-described Embodiment 6.

### Embodiment 3

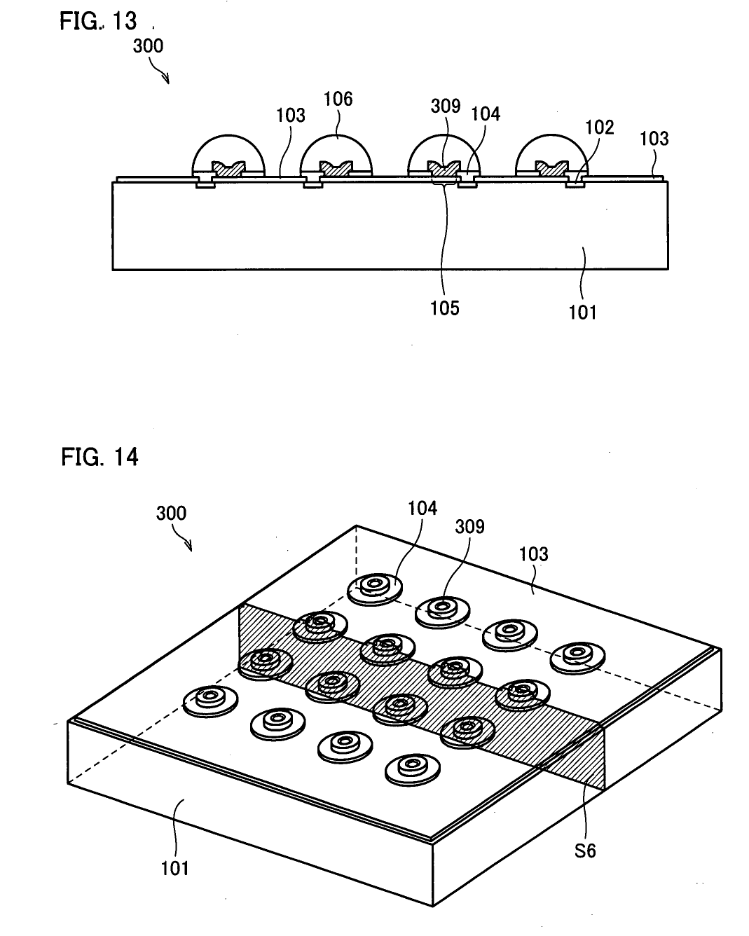

With reference to FIG. 13 to FIG. 16, the following describes another embodiment of the present invention. Note that, the present embodiment is arranged in the same manner as in Embodiment 1 and Embodiment 2 except for points described below. Further, for convenience in descriptions, the same reference numerals are given to members having the same functions as the members illustrated in the drawings of Embodiment 1 and Embodiment 2, and descriptions thereof are omitted.

First, an arrangement of a semiconductor apparatus 300 of the present embodiment is described as follows with reference to FIG. 13 and FIG. 14.

FIG. 13 is a cross sectional view taken along a cross section S6 of the semiconductor apparatus 300 illustrated in FIG. 14.

FIG. 14 is an oblique view illustrating the arrangement of the semiconductor apparatus 300. Note that, the external connection terminal 106 is not illustrated in order to clarify shapes of the conductor section 104 and a protrusion 309.

As illustrated in FIG. 13, in addition to the arrangement of the semiconductor apparatus 100 of Embodiment 1, the semiconductor apparatus 300 of the present embodiment includes the protrusion 309 (level difference).

The protrusion 309 is provided inside the external connection terminal 106 by filling the through hole 105 of the conductor section 104 so as to protrude from the conductor section 104 toward the external connection terminal 106. In more detail, the protrusion 309 is formed so as to be covered the external connection terminal 106 by applying a material along the shape of the through hole 105 of the conductor section 104 so as to have a cyclic outer edge with a certain film thickness.

Further, the protrusion 309 is made of polymer material such as polyimide, polybenzoxazole (PBO), and benzocyclobutene (BCB), and is formed by photolithography or screen printing.

It is preferable that a diameter of the through hole 105 is about ⅓ of the conductor section 104 and a diameter of the outer edge of the protrusion 309 on the conductor section 104 is about ⅔ of the diameter of the conductor section 104. In the present embodiment, in case where a pitch of the external connection terminals 106 is 0.5 mm for example, the diameter of the conductor section 104 is 0.27 mm, and the diameter of the through hole 105 is 0.09 mm, and the diameter of the outer edge of the protrusion 309 is 0.18 mm.

Next, the following describes how the crack acts on the external connection terminal 106 in providing the semiconductor apparatus 300 onto the package substrate.

As in the aforementioned descriptions, also when the semiconductor apparatus 300 is packaged on the package substrate and the crack occurs in the external connection terminal 106 due to the repetitive stresses and the impulse, the crack reaches the protrusion 309 while expanding, so that expansion of the crack stops. That is, presence of an inflectional portion referred to as the protrusion 309 causes the stress to be alleviated, so that expansion of the crack stops in the vicinity of the outer edge of the protrusion 309. Further, the cut portion is freely movable in a horizontal direction to some extent, so that the cut portion is resistive against a slight force.

Thus, connection of the protrusion 309 and the external connection terminal 106 is secured, which does not result in immediate electric openness. That is, it is possible to extend a time period from occurrence of the crack to complete breakage of the external connection terminal 106.

Further, as in the protrusion 209 of the semiconductor apparatus 200 of Embodiment 2, the protrusion 309 is made of the polymer material which is more likely to be deformed than the solder, so that the protrusion 309 itself alleviates the stress exerted to the external connection terminal 106, thereby further enhancing the resistance particularly against the repetitive stresses. As a result, it is possible to improve the packaging reliability.

Further, the semiconductor apparatus 300 is arranged so that the through hole 105 formed on the conductor section 104 is filled with the material constituting the protrusion 309. Thus, an anchor effect thereof allows the protrusion 309 to be provided more stably.

In this manner, the semiconductor apparatus 300 of the present embodiment is arranged so as to include: the conductor section 104 provided on the surface of the semiconductor chip 101 so as to input and output an electric signal; and the external connection terminal 106 formed on the surface of the conductor section 104 so as to joint the conductor section 104 to the package substrate, wherein the conductor section 104 is such that the protrusion 309 is formed on the surface of the conductor section 104 so as to be positioned along the through hole 105 piercing the center of the surface of the conductor section 104 and so as to protrude from the conductor section 104 and so as to be covered by the external connection terminal 106, and the external connection terminal 106 is formed along the protrusion 309.

Generally, when the crack occurs in the external connection terminal 106's outer edge in the vicinity of the joint interface due to the repetitive stresses and the impulse, the continuous joint interface in the direction in which the crack expands allows the crack to immediately expand inwardly from the outer edge of the external connection terminal 106.

However, according to the foregoing arrangement, the conductor section 104 is such that the protrusion 309 is formed on the surface of the conductor section 104 so as to be positioned along the through hole 105 piercing the center of the surface of the conductor section 104 and so as to protrude from the conductor section 104 and so as to be covered by the external connection terminal 106, and the external connection terminal 106 is formed along the protrusion 309, so that the crack which immediately expands inwardly from the outer edge due to the continuous joint interface reaches the protrusion 309 while expanding. At this time, the joint interface has a gap in the direction in which the crack expands, so that the wall of the protrusion 309 appears.

Thus, when the crack reaches the protrusion 309, presence of an inflectional portion referred to as the protrusion 309 causes the stress to be alleviated, so that expansion of the crack stops in the vicinity of the outer edge the protrusion 309.

As a result, connection of the protrusion 309 and the external connection terminal 106 is secured, which does not result in immediate electric openness. That is, it is possible to extend a time period from occurrence of the crack to complete breakage of the external connection terminal 106.

Thus, it is possible to enhance the resistance against the repetitive stresses and the impulse. Therefore, it is possible to prevent immediate breakage of the external connection terminal 106, thereby improving the packaging reliability.

In this manner, the semiconductor apparatus 300 of the present embodiment allows enhancement of the resistance against the repetitive stresses and the impulse and realizes higher packaging reliability.

Further, the protrusion 309 is made of the polymer material which is more likely to be deformed than the solder, so that the protrusion 309 itself alleviates the stress exerted to the external connection terminal 106, thereby further enhancing the resistance particularly against the repetitive stresses. As a result, it is possible to improve the packaging reliability.

Further, the protrusion 309 protrudes from the conductor section 104 so as to fill the through hole 105 of the conductor section 104 positioned inside the external connection terminal 106, so that it is possible to exert the foregoing effect without having any influence on appearance of the semiconductor apparatus 300.

Also in the semiconductor apparatus 300, the semiconductor chip 101 may be stored in another semiconductor apparatus to be wire-bonded. In this case, it is often that the electrode pad 102 is disposed in a vicinity of an outer edge of the semiconductor chip 101.

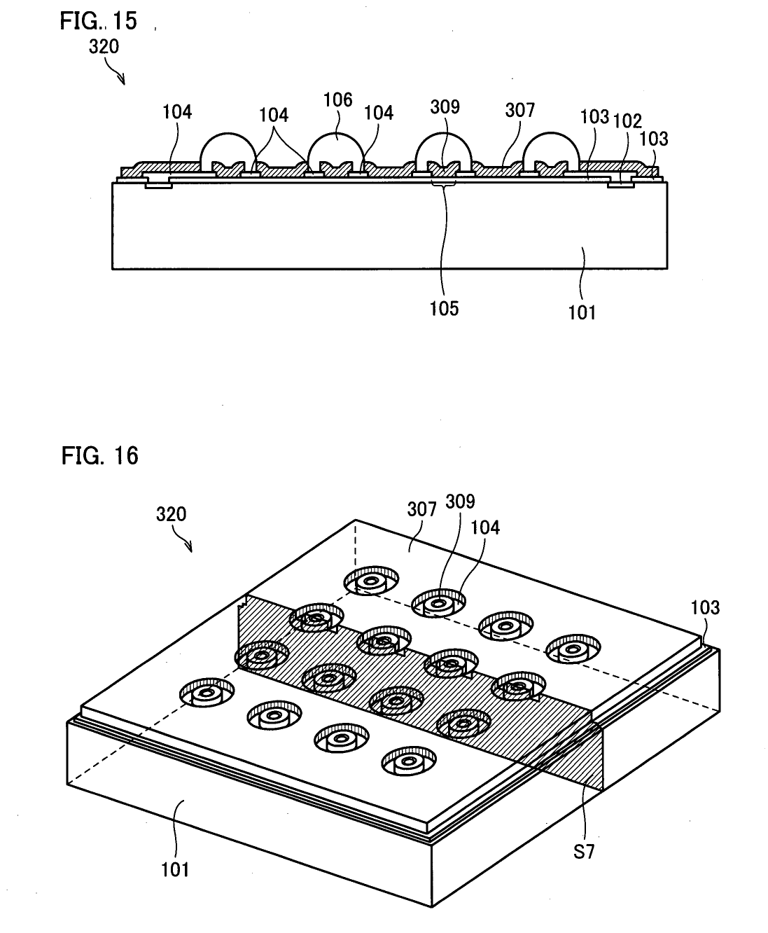

With reference to FIG. 15 and FIG. 16, the following describes an arrangement in which a side face of the conductor section 104 having the external connection terminal 106 thereon and an outline of a top face of the conductor section 104 are coated with an insulation film 307.

FIG. 15 is a cross sectional view taken along a cross section S7 of a semiconductor apparatus 320 illustrated in FIG. 16.

FIG. 16 is an oblique view illustrating an arrangement of the semiconductor apparatus 320 including the insulation film 307. Note that, the external connection terminal 106 is not illustrated in order to clarify shapes of the conductor section 104 and the protrusion 309.

In addition to the arrangement of the semiconductor apparatus 300, the semiconductor apparatus 320 includes the insulation film 307. However, as illustrated in FIG. 15, the electrode pad 102 is disposed in the vicinity of the outer edge of the semiconductor chip 101.

The insulation film 307 covers not only the conductor section 104 extended as a wiring but also a periphery of the external connection terminal 106. Further, a size of the conductor section 104 is larger than the aforementioned size so that the increment corresponds to an amount of the insulation film 307 with which the outline of the top face of the conductor section 104 provided on the external connection terminal 106 is coated. For example, if the amount of the insulation film 307 with which the outline is coated is 0.015 mm, a diameter of the conductor section 104 is set to 0.3 mm.

As a result, even if the electrode pad 102 is disposed in the vicinity of the outer edge of the semiconductor chip 101 and the conductor section 104 is extended and exposed so as to connect the external connection terminal 106 and the electrode pad 102 to each other, the exposed portion of the conductor section 104 is covered by the insulation film 307, so that it is possible to prevent corrosion of the exposed portion and occurrence of current leak.

Note that, the insulation film 307 is formed in the same step and at the same time as in the protrusion 309. This will be detailed in a below-described Embodiment 7.

### Embodiment 4

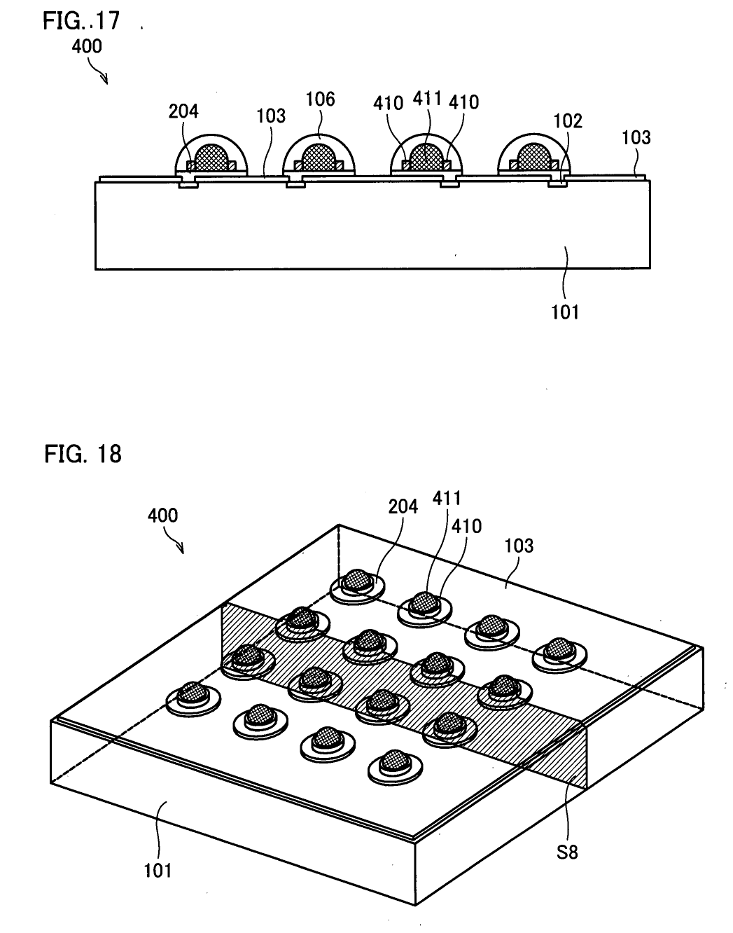

With reference to FIG. 17 to FIG. 20, the following describes another embodiment of the present invention.

Note that, the present embodiment is arranged in the same manner as in Embodiment 1, Embodiment 2, and Embodiment 3 except for points described below. Further, for convenience in descriptions, the same reference numerals are given to members having the same functions as the members illustrated in the drawings of Embodiment 1, Embodiment 2, and Embodiment 3, and descriptions thereof are omitted.

First, an arrangement of a semiconductor apparatus 400 of the present embodiment is described as follows with reference to FIG. 17 and FIG. 18.

FIG. 17 is a cross sectional view taken along a cross section S8 of the semiconductor apparatus 400 illustrated in FIG. 18.

FIG. 18 is an oblique view illustrating the arrangement of the semiconductor apparatus 400. Note that, the external connection terminal 106 is not illustrated in order to clarify shapes of the conductor section 204, a dam 410, and a protrusion 411.

As illustrated in FIG. 17, in addition to the arrangement of the semiconductor apparatus 200 of Embodiment 2 except for the protrusion 209, the semiconductor apparatus 400 of the present embodiment includes the dam 410 (level difference) and the protrusion 411 (level difference).

The dam 410 prevents a material of the protrusion 411 from extending over an area of the conductor section 204 in forming the protrusion 411. The dam 410 is formed in a cyclic shape before forming the protrusion 411.

Further, the dam 410 is made of polymer material such as polyimide, polybenzoxazole (PBO), and benzocyclobutene (BCB), and is formed by photolithography or screen printing.

The protrusion 411 has a dome shape and is provided inside the external connection terminal 106 so as to be positioned in a center of a surface of the conductor section 204. That is, the protrusion 411 is formed so that a face at which the external connection terminal 106 and the conductor section 204 are in contact with each other is covered by the external connection terminal 106.

Note that, a volume of the protrusion 411 is made larger than the protrusion 209 of Embodiment 2 in order to enhance the effect of alleviating the stress exerted to the external connection terminal 106. Further, the protrusion 411 is made of elastomer and is formed by dispenser or screen printing.

It is preferable that a diameter of the protrusion 411 is ⅓ to ⅔ of a diameter of the conductor section 204. In the present embodiment, in case where a pitch of the external connection terminal 106 is 0.5 mm for example, the diameter of the conductor section 204 is 0.27 mm, and the diameter of the protrusion 411 is 0.09 mm to 0.18 mm. A height of the protrusion 411 is 0.03 to 0.15 mm.

Next, the following describes how the crack acts on the external connection terminal 106 in packaging the semiconductor apparatus 400 onto the package substrate.

As in the aforementioned descriptions, also when the semiconductor apparatus 400 is packaged on the package substrate and the crack occurs in the external connection terminal 106 due to the repetitive stresses and the impulse, the crack reaches the dam 410 while expanding, so that expansion of the crack stops. That is, presence of an inflectional portion referred to as the dam 410 causes the stress to be alleviated, so that expansion of the crack stops in the vicinity of the outer edge of the dam 410. Further, the cut portion is freely movable in a horizontal direction to some extent, so that the cut portion is resistive against a slight force.

Thus, connection among the dam 410, the protrusion 411, and the external connection terminal 106 is secured, which does not result in immediate electric openness. That is, it is possible to extend a time period from occurrence of the crack to complete breakage of the external connection terminal 106.

Further, the protrusion 411 is made of less elastic elastomer, so that the protrusion 411 alleviates the repetitive stresses, thereby reducing a stress load exerted to the joint portion. Therefore, the crack hardly occurs in the external connection terminal 106. As a result, it is possible to further improve the packaging reliability.

In this manner, the semiconductor apparatus 400 of the present embodiment is arranged so as to include: the conductor section 204 provided on the surface of the semiconductor chip 101 so as to input and output an electric signal; and the external connection terminal 106 provided on the surface of the conductor section 204 so as to joint the conductor section 204 to the package substrate, wherein the conductor section 204 includes (i) the protrusion 411 formed in a dome shape on the center of the surface of the conductor section 204 so as to be covered by the external connection terminal 106 and (ii) the dam 410 formed so as to surround the protrusion 411 and so as to be covered by the external connection terminal 106, and the external connection terminal 106 is formed along the dam 410 and the protrusion 411.

Generally, when the crack occurs in the external connection terminal 106's outer edge in the vicinity of the joint interface due to the repetitive stresses and the impulse, the continuous joint interface in the direction in which the crack expands allows the crack to immediately expand inwardly from the outer edge of the external connection terminal 106.

However, according to the foregoing arrangement, the conductor section 204 includes (i) the protrusion 411 formed in a dome shape on the center of the surface of the conductor section 204 so as to be covered by the external connection terminal 106 and (ii) the dam 410 formed so as to surround the protrusion 411 and so as to be covered by the external connection terminal 106, and the external connection terminal 106 is formed along the dam 410 and the protrusion 411, so that the crack which immediately expands inwardly from the outer edge due to the continuous joint interface reaches the dam 410 while expanding. At this time, the joint interface has a gap in the direction in which the crack expands, so that the wall of the dam 410 appears.

Thus, when the crack reaches the dam 410, presence of an inflectional portion referred to as the dam 410 causes the stress to be alleviated, so that expansion of the crack stops in the vicinity of the outer edge of the dam 410.

As a result, connection among the dam 410, the protrusion 411, and the external connection terminal 106 is secured, which does not result in immediate electric openness. That is, it is possible to extend a time period from occurrence of the crack to complete breakage of the external connection terminal 106.

Thus, it is possible to enhance the resistance against the repetitive stresses and the impulse. Therefore, it is possible to prevent immediate breakage of the external connection terminal 106, thereby improving the packaging reliability.

In this manner, the semiconductor apparatus 400 of the present embodiment allows enhancement of the resistance against the repetitive stresses and the impulse and realizes higher packaging reliability.

Further, the protrusion 411 is made of the less elastic elastomer, so that the repetitive stresses are alleviated, thereby reducing a stress load exerted to the joint portion. Therefore, the crack hardly occurs in the external connection terminal 106. As a result, it is possible to further improve the packaging reliability.

Further, the dam 410 and the protrusion 411 are provided on the surface of the conductor section 204 so as to be covered by the external connection terminal 106, so that it is possible to exert the foregoing effect without having any influence on appearance of the semiconductor apparatus 400.

Also in the semiconductor apparatus 400, the semiconductor chip 101 may be stored in another semiconductor apparatus to be wire-bonded. In this case, it is often that the electrode pad 102 is disposed in a vicinity of an outer edge of the semiconductor chip 101.

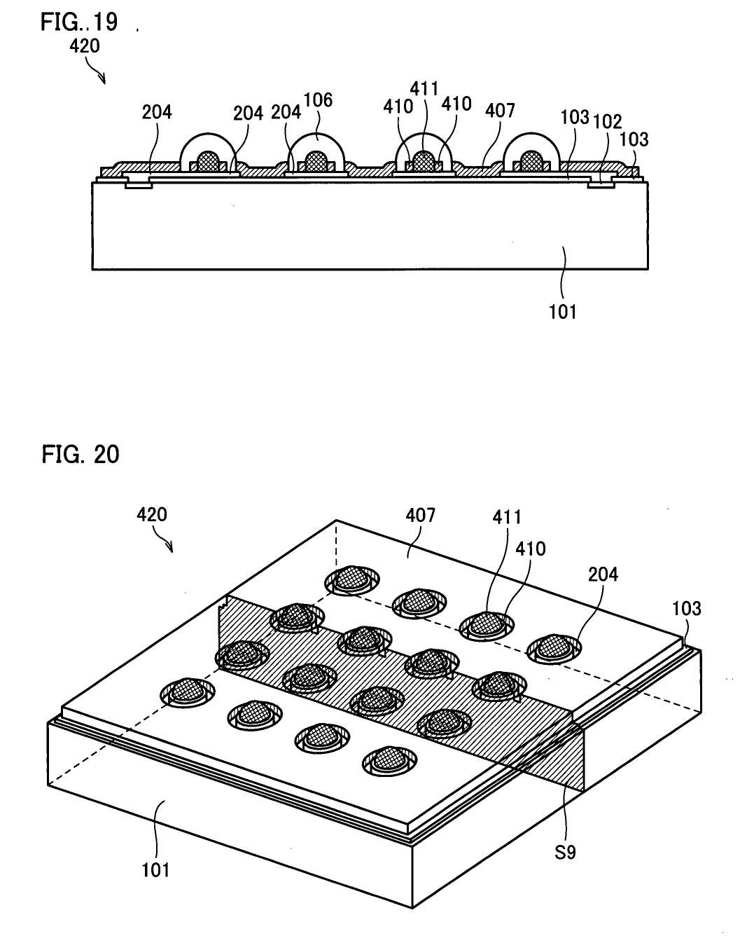

With reference to FIG. 19 and FIG. 20, the following describes an arrangement in which a side face of the conductor section 204 having the external connection terminal 106 thereon and an outline of a top face of the conductor section 204 are coated with an insulation film 407.

FIG. 19 is a cross sectional view taken along a cross section S9 of a semiconductor apparatus 420 illustrated in FIG. 20.

FIG. 20 is an oblique view illustrating an arrangement of the semiconductor apparatus 420 including the insulation film 407. Note that, the external connection terminal 106 is not illustrated in order to clarify shapes of the conductor section 204, the dam 410, and the protrusion 411.

In addition to the arrangement of the semiconductor apparatus 400, the semiconductor apparatus 420 includes the insulation film 407. However, as illustrated in FIG. 19, the electrode pad 102 is disposed in the vicinity of the outer edge of the semiconductor chip 101.

The insulation film 407 covers not only the conductor section 204 extended as a wiring but also a periphery of the external connection terminal 106. Further, a size of the conductor section 204 is larger than the aforementioned size so that the increment corresponds to an amount of the insulation film 407 with which the outline of the top face of the conductor section 204 provided on the external connection terminal 106 is coated. For example, if the amount of the insulation film 407 with which the outline is coated is 0.015 mm, a diameter of the conductor section 204 is set to 0.3 mm.

As a result, even if the electrode pad 102 is disposed in the vicinity of the outer edge of the semiconductor chip 101 and the conductor section 204 is extended and exposed so as to connect the external connection terminal 106 and the electrode pad 102 to each other, the exposed portion of the conductor section 204 is covered by the insulation film 407, so that it is possible to prevent corrosion of the exposed portion and occurrence of current leak.

Note that, the insulation film 407 is formed in the same step and at the same time as in the dam 410. This will be detailed in a below-described Embodiment 8.

### Embodiment 5

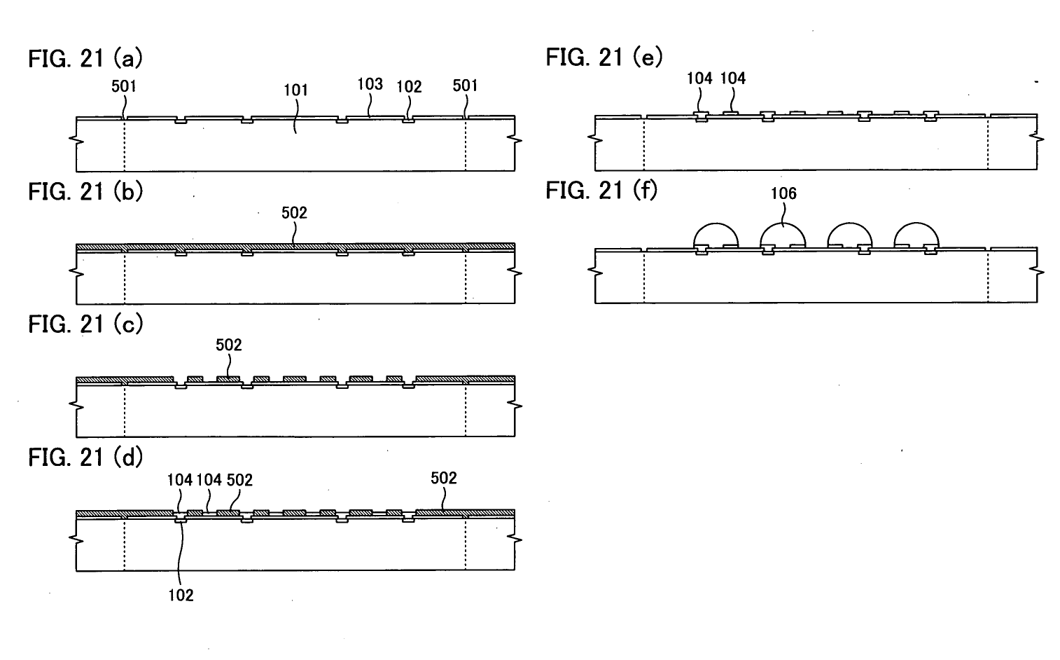

With reference to FIG. 21(a) to FIG. 21(f), the following describes another embodiment of the present invention. Note that, the present embodiment is arranged in the same manner as in Embodiment 1 to Embodiment 4 except for points described below. Further, for convenience in descriptions, the same reference numerals are given to members having the same functions as the members illustrated in the drawings of Embodiment 1 to Embodiment 4, and descriptions thereof are omitted.

Each of FIG. 21(a) to FIG. 21(f) is a diagram illustrating a manufacturing process of the semiconductor apparatus 100.

A manufacturing method of the semiconductor apparatus 100 illustrated in Embodiment 1 is described as follows.

First, as illustrated in FIG. 21(a), a chromium (Cr) thin film and a copper (Cu) thin film are formed in this order on an entire surface of a wafer (the semiconductor chip 101, a dicing position 501) including a semiconductor integrated circuit and an insulation layer 103 provided on a top surface of the semiconductor integrated circuit by using a sputtering device. Note that, each thin film is extremely thin, so that illustration thereof is omitted.

Next, as illustrated in FIG. 21(b), a photoresist 502 is applied to an entire surface of the copper thin film by a spin coater.

Subsequently, as illustrated in FIG. 21(c), an exposing device and an etching device remove the photoresist 502 from a region where the conductor section 104 is to be subsequently formed. At this time, in the portion from which the photoresist 502 has been removed, the copper (Cu) thin film formed by the previous sputtering is exposed.

Subsequently, as illustrated in FIG. 21(d), a portion at which the photoresist 502 is exposed is plated with copper (conductor section 104) by using an electrolytic plating device with the copper (Cu) thin film regarded as a contact point of the electrode. The electrode pad 102 is connected to the conductor section 104 so that the thin film formed by the previous sputtering is sandwiched therebetween.

Subsequently, as illustrated in FIG. 21(e), the photoresist 502 is completely removed by a peeling solution. At this time, the copper thin film formed by the sputtering or copper of the plating exists on the surface of the wafer, so that copper is exposed at the entire surface of the wafer. Next, the exposed copper thin film formed by the sputtering is completely removed (not shown) by a copper etching solution. However, also the copper of the plating is dissolved, but the copper of the plating is much thicker than the copper formed by the sputtering, so that the copper of the plating finally remains as a pattern. Note that, also the copper having been formed by the sputtering and positioned under the copper of the plating remains. Next, the exposed chromium thin film is completely removed (not shown) by a chromium etching solution.

Subsequently, as illustrated in FIG. 21(f), a solder ball is placed on a predetermined position by a solder ball placing device or a solder paste is printed on a predetermined position by a printing device, and a reflow process is carried out so as to form the external connection terminal 106.

Lastly, the dicing position 501 is diced by a dicing device into semiconductor chips 101, thereby completing formation of semiconductor apparatuses 100.

In this manner, the semiconductor apparatus 100 illustrated in FIG. 1 and FIG. 2 is formed.

### Embodiment 6

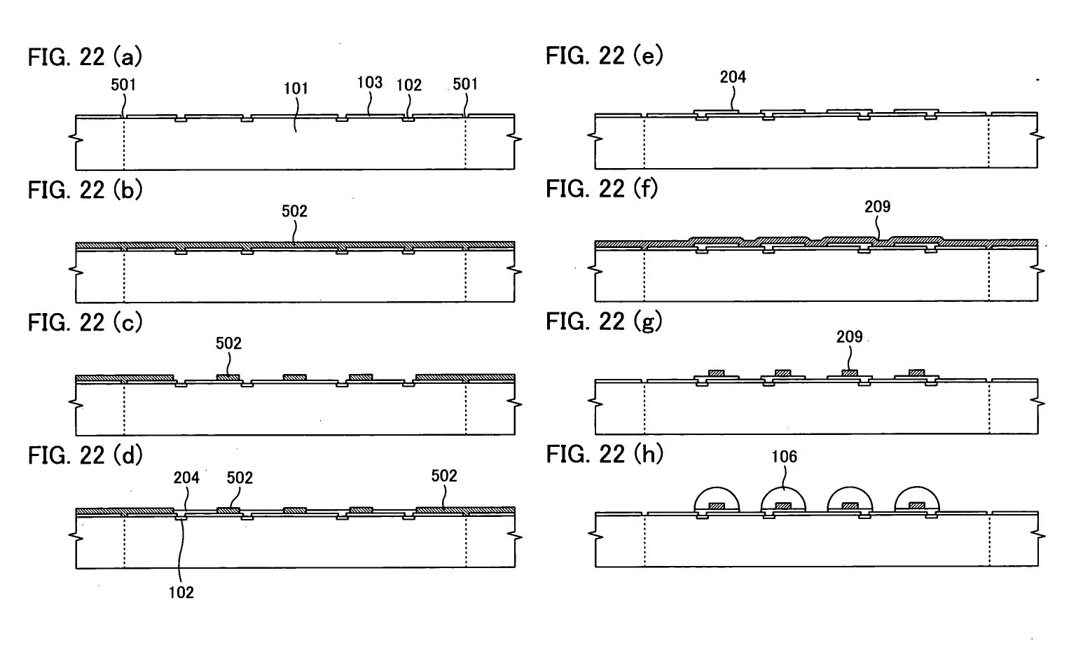

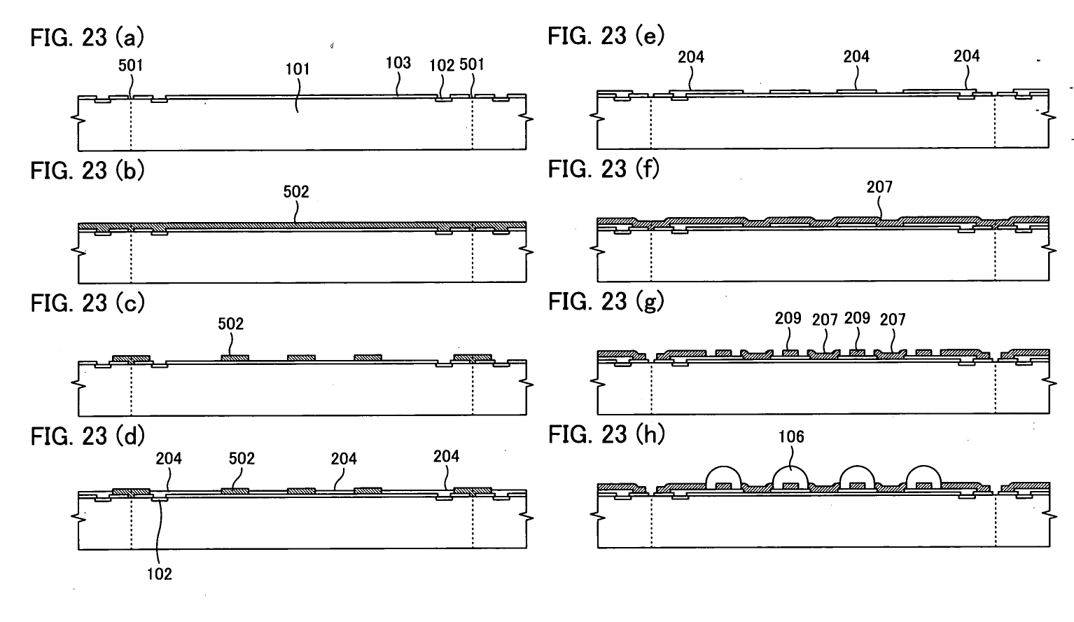

With reference to FIG. 22(a) to FIG. 22(h) and FIG. 23(a) to FIG. 23(h), the following describes another embodiment of the present invention. Note that, the present embodiment is arranged in the same manner as in Embodiment 1 to Embodiment 5 except for points described below. Further, for convenience in descriptions, the same reference numerals are given to members having the same functions as the members illustrated in the drawings of Embodiment 1 to Embodiment 5, and descriptions thereof are omitted.

Each of FIG. 22(a) to FIG. 22(h) is a diagram illustrating a manufacturing process of the semiconductor apparatus 200.

A manufacturing method of the semiconductor apparatus 200 illustrated in Embodiment 2 is described as follows.

First, the state illustrated in FIG. 22(a) is realized in the same manner as in FIG. 21(a), and the state illustrated in FIG. 22(b) is realized in the same manner as in FIG. 21(b).

Subsequently, as illustrated in FIG. 22(c), an exposing device and an etching device remove the photoresist 502 from a region where the conductor section 204 is to be subsequently formed. At this time, in the portion from which the photoresist 502 has been removed, the copper (Cu) thin film formed by the previous sputtering is exposed.

Subsequently, the state illustrated in FIG. 22(d) is realized in the same manner as in FIG. 21(d), and the state illustrated in FIG. 22(e) is realized in the same manner as in FIG. 21(e).

Subsequently, as illustrated in FIG. 22(f), the protrusion 209 (photosensitive polymer) is applied to an entire top surface by a spin coater.

Subsequently, as illustrated in FIG. 22(g), the exposing device and the etching device remove the protrusion 209 from a portion other than a region where the protrusion 209 should remain. In more detail, patterning is carried out so that the protrusion 209 remains in a center of the conductor section 204 on which the external connection terminal 106 is formed, thereby using the remaining portion as the protrusion 209. Further, the protrusion 209 is cured by a heat processing oven.

Subsequently, as illustrated in FIG. 22(h), a solder ball is placed on a predetermined position by a solder ball placing device or a solder paste is printed on a predetermined position by a printing device, and a reflow process is carried out so as to form the external connection terminal 106.

Lastly, the dicing position 501 is diced by a dicing device into semiconductor chips 101, thereby completing formation of semiconductor apparatuses 200.

In this manner, the semiconductor apparatus 200 illustrated in FIG. 8 and FIG. 9 is formed.

Next, a manufacturing method of the semiconductor apparatus 220 illustrated in Embodiment 2 is described as follows.

Each of FIG. 23(a) to FIG. 23(h) is a diagram illustrating a manufacturing process of the semiconductor apparatus 220.

First, the states illustrated in FIG. 23(a) to FIG. 23(f) are realized in the same manner as in FIG. 22(a) to FIG. 22(f).

Note that, in case where the insulation film 207 is non-photosensitive polymer in FIG. 23(f), it may be so arranged that: the photoresist 502 illustrated in FIG. 23(b) is placed on the insulation film 207, and patterning is carried out by the exposing device and the etching device so as to etch an unnecessary portion of the polymer, thereby peeling the photoresist 502.

Subsequently, as illustrated in FIG. 23(g), the exposing device and the etching device remove the insulation film 207 from a region where the external connection terminal 106 is to be subsequently formed and from the dicing position 501. Further, the insulation film 207 is cured by a heat processing oven. Note that, at this time, the center of the conductor section 104 on which the external connection terminal 106 is to be formed so as to be positioned in the center is patterned so that the insulation film 207 remains, thereby using the remaining portion in the center as the protrusion 209.

Subsequently, as illustrated in FIG. 23(h), a solder ball is placed on a predetermined position by a solder ball placing device or a solder paste is printed on a predetermined position by a printing device, and a reflow process is carried out so as to form the external connection terminal 106.

Lastly, the dicing position 501 is diced by a dicing device into semiconductor chips 101, thereby completing formation of semiconductor apparatuses 220.

In this manner, the semiconductor apparatus 220 illustrated in FIG. 11 and FIG. 12 is formed.

In this case, as illustrated in FIG. 23(g), the protrusion 209 is formed by using the same material and at the same time as in the insulation film 207, so that it is possible to carry out a step of manufacturing a conventional wafer CSP without any change. Therefore, the cost does not increase.

### Embodiment 7

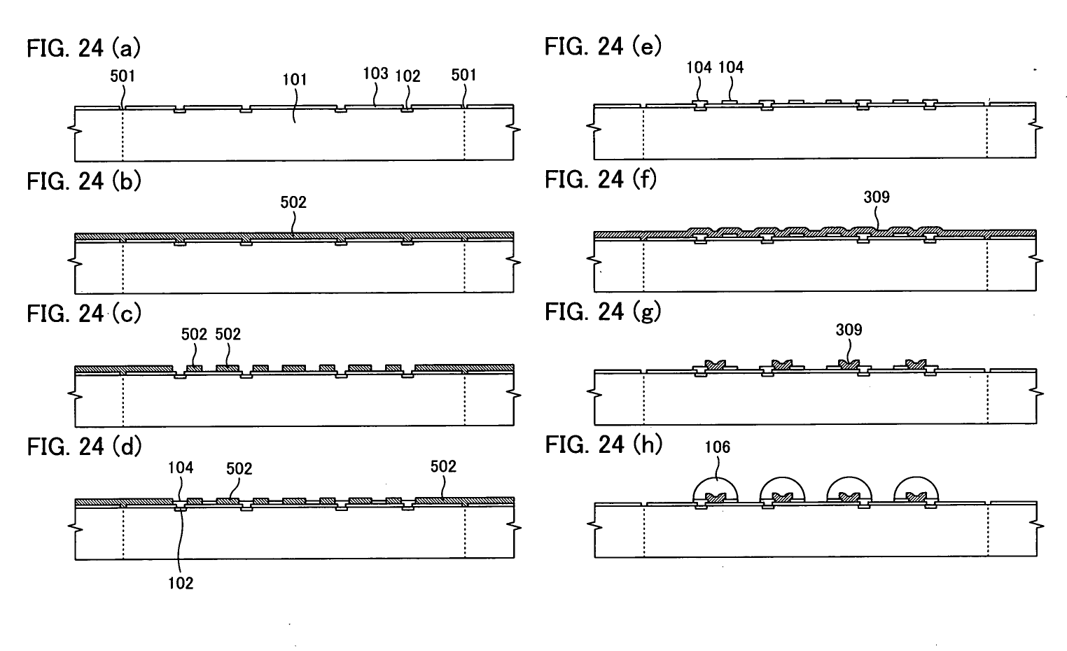

With reference to FIG. 24(a) to FIG. 24(h), the following describes another embodiment of the present invention. Note that, the present embodiment is arranged in the same manner as in Embodiment 1 to Embodiment 6 except for points described below. Further, for convenience in descriptions, the same reference numerals are given to members having the same functions as the members illustrated in the drawings of Embodiment 1 to Embodiment 6, and descriptions thereof are omitted.

Each of FIG. 24(a) to FIG. 24(h) is a diagram illustrating a manufacturing process of the semiconductor apparatus 300.

First, the states illustrated in FIG. 24(a) to FIG. 24(e) are realized in the same manner as in FIG. 21(a) to FIG. 21(e).

Next, as illustrated in FIG. 24(f), the protrusion 309 (photosensitive polymer) is applied to an entire top surface by a spin coater.

Subsequently, as illustrated in FIG. 24(g), the exposing device and the etching device remove the protrusion 309 from a portion other than a region where the protrusion 309 should remain. In more detail, patterning is carried out so that the protrusion 309 remains in a center of the conductor section 104 on which the external connection terminal 106 is formed, thereby using the remaining portion as the protrusion 309. Further, the protrusion 309 is cured by a heat processing oven.

Subsequently, as illustrated in FIG. 24(h), a solder ball is placed on a predetermined position by a solder ball placing device or a solder paste is printed on a predetermined position by a printing device, and a reflow process is carried out so as to form the external connection terminal 106.

Lastly, the dicing position 501 is diced by a dicing device into semiconductor chips 101, thereby completing formation of semiconductor apparatuses 300.

In this manner, the semiconductor apparatus 300 illustrated in FIG. 13 and FIG. 14 is formed.

Further, also in case of a manufacturing process of the semiconductor apparatus 320, the semiconductor apparatus 320 is manufactured in the same manner as in the manufacturing process of the semiconductor apparatus 220, so that the protrusion 309 can be formed by using the same material and at the same time as in the insulation film 307. Thus, it is possible to carry out a step of manufacturing a conventional wafer CSP without any change. Therefore, the cost does not increase.

### Embodiment 8

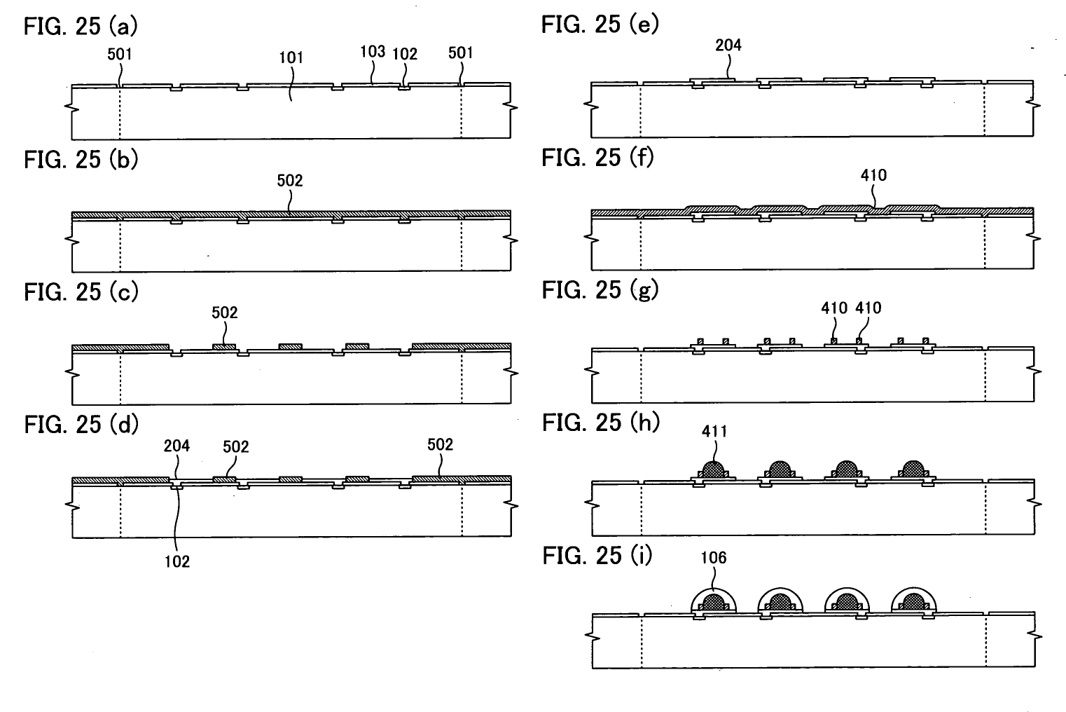

With reference to FIG. 25(a) to FIG. 25(i), the following describes another embodiment of the present invention. Note that, the present embodiment is arranged in the same manner as in Embodiment 1 to Embodiment 7 except for points described below. Further, for convenience in descriptions, the same reference numerals are given to members having the same functions as the members illustrated in the drawings of Embodiment 1 to Embodiment 7, and descriptions thereof are omitted.

Each of FIG. 25(a) to FIG. 25(i) is a diagram illustrating a manufacturing process of the semiconductor apparatus 400.

First, the states illustrated in FIG. 25(a) to FIG. 25(f) are realized in the same manner as in FIG. 22(a) to FIG. 22(f).

Subsequently, as illustrated in FIG. 25(g), the exposing device and the etching device remove the dam 410 from a portion other than a region where the dam 410 should remain. In more detail, the center of the conductor section 104 on which the external connection terminal 106 is to be formed so as to be positioned in the center is patterned so that the dam 410 remains, thereby using the remaining portion in the center as the dam 410. Further, the dam 410 is cured by a heat processing oven.

Subsequently, as illustrated in FIG. 25(h), the protrusion 411 is provided so as to be positioned inside an internal periphery of the dam 410, and the protrusion 411 is cured by a heat processing oven.

Subsequently, as illustrated in FIG. 25(i), a solder ball is placed on a predetermined position by a solder ball placing device or a solder paste is printed on a predetermined position by a printing device, and a reflow process is carried out so as to form the external connection terminal 106.

Lastly, the dicing position 501 is diced by a dicing device into semiconductor chips 101, thereby completing formation of semiconductor apparatuses 400.

In this manner, the semiconductor apparatus 400 illustrated in FIG. 17 and FIG. 18 is formed.

Further, also in case of a manufacturing process of the semiconductor apparatus 420, the semiconductor apparatus 420 is manufactured in the same manner as in the manufacturing process of the semiconductor apparatuses 220 and 320, so that the dam 410 can be formed by using the same material and at the same time as in the insulation film 407. Thus, it is possible to carry out a step of manufacturing a conventional wafer CSP without any change. Therefore, the cost does not increase.

### Embodiment 9

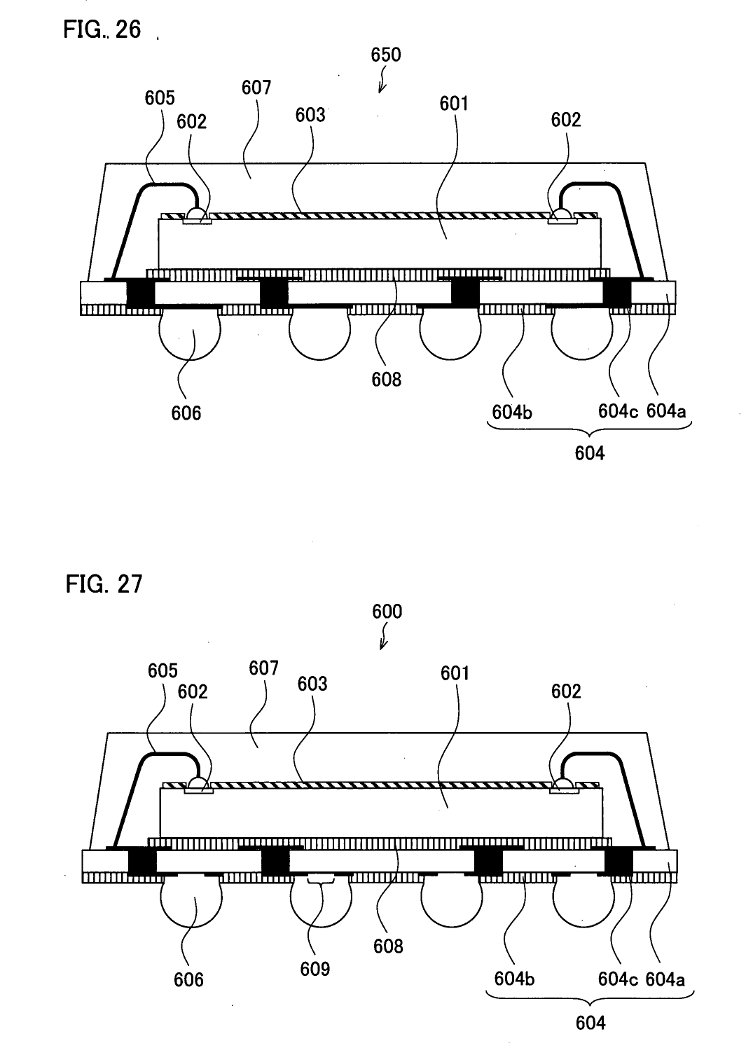

With reference to FIG. 26 to FIG. 28, the following describes another embodiment of the present invention. Note that, the present embodiment is arranged in the same manner as in Embodiment 1 to Embodiment 8 except for points described below. Further, for convenience in descriptions, the same reference numerals are given to members having the same functions as the members illustrated in the drawings of Embodiment 1 to Embodiment 8, and descriptions thereof are omitted.

FIG. 26 is a cross sectional view illustrating an arrangement of a conventional semiconductor apparatus 650.

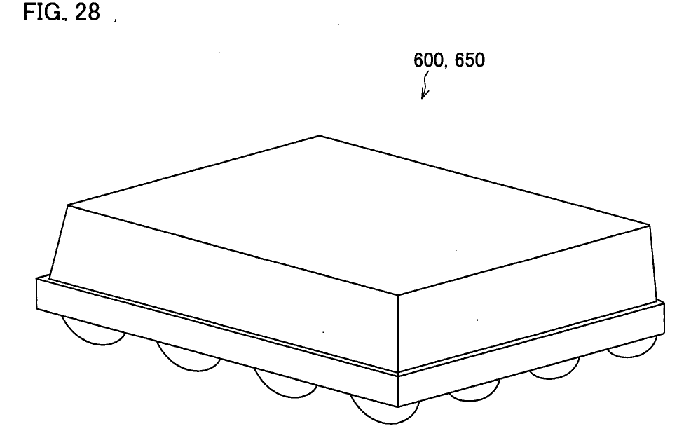

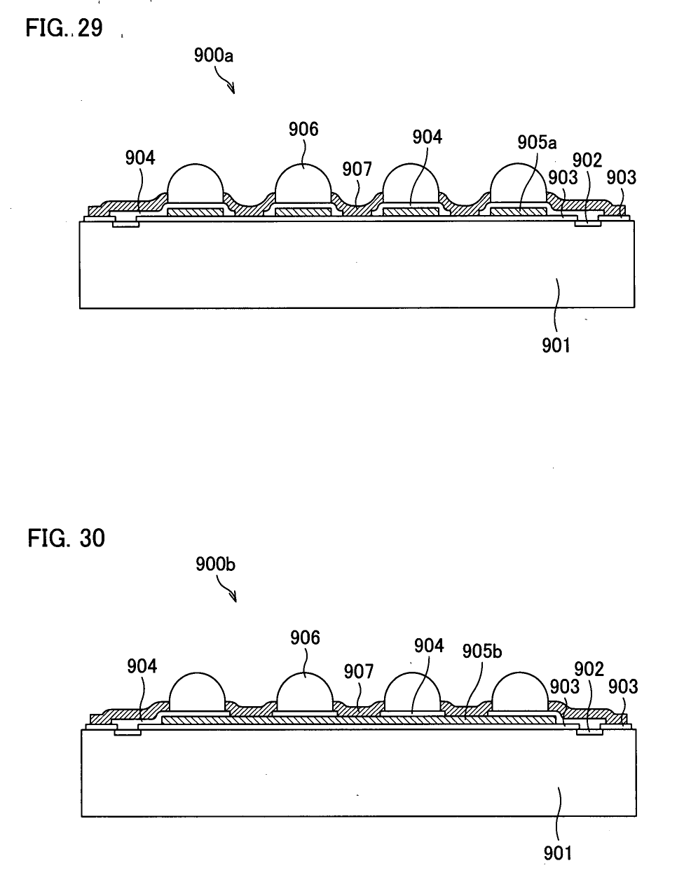

FIG. 27 is a cross sectional view illustrating an arrangement of a semiconductor apparatus 600.

FIG. 28 is an oblique view illustrating an arrangement of the semiconductor apparatuses 600 or 650.

Each of the aforementioned embodiments described the structure of the semiconductor apparatus as the wafer level CSP. However, the semiconductor apparatus of the present embodiment may be applied not only to the wafer level CSP but also another semiconductor apparatus in which a solder is provided on an interposer substrate as the external connection terminal. Examples of the aforementioned another semiconductor apparatus include a ball grid array package (BGA) and the like.

In the present embodiment, the arrangement of the BGA semiconductor apparatus 600 is described as follows as an example of the aforementioned another semiconductor apparatus.

First, with reference to FIG. 26, the arrangement of the conventional BGA semiconductor apparatus 650 is described. Further, with reference to FIG. 27, the following describes the arrangement of the semiconductor apparatus 600 obtained by applying the arrangement of the semiconductor apparatus of the present invention to the conventional BGA semiconductor apparatus 650.

The conventional semiconductor apparatus 650 includes a semiconductor chip 601, an electrode pad 602, an insulation layer 603, an interposer substrate 604 (an insulation base section 604a, a surface protection resist section 604b, a conductor section 604c including a metal pattern section and a through hole section), a metal wire 605, an external connection terminal 606 (joint terminal), a sealing resin 607, and a die-bond sheet 608.

A surface of the semiconductor chip 601 is covered by the insulation layer 603. Note that, the insulation layer 603 has an opening in a position corresponding to the electrode pad 602 on a surface of the semiconductor chip 601 which electrode pad 602 is bonded to the metal wire 605.

Further, the metal wire 605 has another end which is not connected to the electrode pad 602, and the aforementioned another end is bonded to the conductor section 604c of the interposer substrate 604 above which the semiconductor chip 601 is fixed via the die-bond sheet 608. The conductor section 604c is wire-connected to the external connection terminal 606.

Further, the semiconductor chip 601 is covered by not only the metal wire 605 but also the sealing resin 607. In this manner, the semiconductor apparatus 650 is entirely protected.

While, in addition to the arrangement of the semiconductor apparatus 650, the semiconductor apparatus 600 of the present embodiment is arranged so that a through hole 609 (level difference) is formed on the conductor section 604c of the interposer substrate 604.

Note that, the conductor section 604c, the through hole 609, and the external connection terminal 606 of the semiconductor apparatus 600 of the present embodiment respectively correspond to the conductor section 104, the through hole 105, and the external connection terminal 106 of the semiconductor apparatus 100 of Embodiment 1.

As a result, also the semiconductor apparatus 600 of the present embodiment can exhibit the same effect as in the semiconductor apparatus 100 of Embodiment 1.

Note that, the foregoing description explained the case where the through hole 609 is formed in the conductor section 604c of the interposer substrate 604. However, the present invention is not limited to this, and the structures of the semiconductor apparatuses illustrated in Embodiments 1 to 4 may be adopted.

The present invention is not limited to the description of the embodiments above, but may be altered by a skilled person within the scope of the claims. An embodiment based on a proper combination of technical means disclosed in different embodiments is encompassed in the technical scope of the present invention.

The present invention is favorably applicable to a semiconductor apparatus including therein a semiconductor integrated circuit used for an electronic device such as an information communication device.

As described above, a semiconductor apparatus of the present embodiment includes: a conductor section provided on a surface of a semiconductor chip so as to input and output an electric signal; and a joint terminal provided on the surface of the conductor section so as to joint the conductor section to a package substrate, wherein the conductor section has a level difference on its surface, and the joint terminal is provided along the level difference.

Therefore, the semiconductor apparatus of the present invention allows enhancement of the resistance against the repetitive stresses and the impulse and realizes higher packaging reliability. Further, the level difference is formed on the surface of the conductor section positioned inside the joint terminal, so that it is possible to exert the foregoing effect without having any influence on appearance of the semiconductor apparatus.

Further, a method of the present embodiment for manufacturing a semiconductor apparatus including: a conductor section provided on a surface of a semiconductor chip so as to input and output an electric signal; and a joint terminal provided on the surface of the conductor section so as to joint the conductor section to a package substrate, said method comprising the steps of: forming a level difference on the surface of the conductor section; and forming the joint terminal along the level difference.

Therefore, the method according to the present invention for manufacturing the semiconductor apparatus allows enhancement of the resistance against the repetitive stresses and the impulse and realizes higher packaging reliability. Further, the level difference is formed on the surface of the conductor section positioned inside the joint terminal, so that it is possible to manufacture the semiconductor apparatus which can exert the foregoing effect without having any influence on appearance of the semiconductor apparatus.

Further, it is preferable to arrange the semiconductor apparatus of the present embodiment so that a through hole which pierces a center of the surface of the conductor section is provided so as to form the level difference.

Further, it is preferable to arrange the method of the present embodiment so that a through hole which pierces a center of the surface of the conductor section is provided so as to form the level difference.

According to the foregoing arrangements, the level difference is formed by forming the through hole piercing the center of the surface of the conductor section, so that mere formation of the through hole makes it possible to easily form the level difference.

Further, it is preferable to arrange the semiconductor apparatus of the present embodiment so that a protrusion formed in a cylindrical shape so as to be covered by the joint terminal is provided in the center of the surface of the conductor section so as to form the level difference.

Further, it is preferable to arrange the method of the present embodiment for manufacturing a semiconductor apparatus so that a protrusion formed in a cylindrical shape so as to be covered by the joint terminal is provided in the center of the surface of the conductor section so as to form the level difference.

According to the foregoing arrangements, a protrusion formed in a cylindrical shape so as to be covered by the joint terminal is provided in the center of the surface of the conductor section so as to form the level difference, so that mere formation of the protrusion makes it possible to easily form the level difference.

Further, it is preferable to arrange the semiconductor apparatus of the present embodiment so that a protrusion formed along the through hole piercing the center of the surface of the conductor section so as to protrude from the conductor section and so as to be covered by the joint terminal is provided so as to form the level difference.

Further, it is preferable to arrange the method of the present embodiment for manufacturing a semiconductor apparatus so that a protrusion formed along the through hole piercing the center of the surface of the conductor section so as to protrude from the conductor section and so as to be covered by the joint terminal is provided so as to form the level difference.

According to the foregoing arrangements, a protrusion formed along the through hole piercing the center of the surface of the conductor section so as to protrude from the conductor section and so as to be covered by the joint terminal is provided so as to form the level difference, mere formation of the protrusion makes it possible to easily form the level difference.

Further, it is preferable to arrange the semiconductor apparatus of the present embodiment so that: a protrusion formed in the center of the surface of the conductor section and formed in a dome shape so as to be covered by the joint terminal is provided, and a dam surrounding the protrusion and formed so as to be covered by the joint terminal is provided, so as to form the level difference.

Further, it is preferable to arrange the method of the present embodiment for manufacturing a semiconductor apparatus so as to includes the steps of: providing a dam formed in the center of the surface of the conductor section and formed in a circular shape so as to be covered by the joint terminal; and providing a protrusion formed inside the dam and formed in a dome shape so as to be covered by the joint terminal, wherein the steps are carried out so as to form the level difference.

According to the foregoing arrangements, a protrusion formed in the center of the surface of the conductor section and formed in a dome shape so as to be covered by the joint terminal is provided, and a dam surrounding the protrusion and formed so as to be covered by the joint terminal is provided, so as to form the level difference, so that mere formation of the protrusion and the dam makes it possible to easily form the level difference.

Further, it is preferable to arrange the semiconductor apparatus of the present embodiment so as to include an insulation film with which the conductor section is coated.

Further, it is preferable to arrange the method of the present embodiment for manufacturing a semiconductor apparatus so that an exposed portion of the conductor section is coated with an insulation film.

According to the foregoing arrangements, an exposed portion of the conductor section is coated with an insulation film, so that it is possible to prevent corrosion of the exposed portion and occurrence of an electric leak.

Further, it is preferable to arrange the semiconductor apparatus of the present embodiment so that the protrusion is made of polymer material.

According to the foregoing arrangement, the protrusion is made of the polymer material which is more likely to be deformed than the solder used as a material constituting the joint terminal for example, so that the protrusion itself alleviates the stress exerted to the joint terminal, thereby further enhancing the resistance particularly against the repetitive stresses. As a result, it is possible to improve the packaging reliability.

Further, it is preferable to arrange the semiconductor apparatus of the present embodiment: the insulation film is made of the same material as the protrusion, and the protrusion is formed in the same step as the insulation film.

Further, it is preferable to arrange the method of the present embodiment for manufacturing a semiconductor apparatus: the insulation film is made of the same material as the protrusion, and the protrusion is formed in the same step as the insulation film.

According to the foregoing arrangements, the protrusion and the insulation film are formed in the same step, so that it is possible to carry out a conventional step of forming a surface-mounted package without any change. Therefore, it is possible to suppress increase of the cost.

Further, it is preferable to arrange the semiconductor apparatus of the present embodiment so that the protrusion is made of elastomer.

According to the foregoing arrangement, elastomer is less elastic, so that alleviation of repetitive stresses allows reduction of a stress load exerted to the joint portion. Therefore, the crack hardly occurs in the joint terminal. Thus, it is possible to further improve the joint reliability.

Further, it is preferable to arrange the semiconductor apparatus of the present embodiment so that: the insulation film is made of the same material as the dam, and the dam is formed in the same step as the insulation film.

Further, it is preferable to arrange the method of the present embodiment for manufacturing a semiconductor apparatus so that: the insulation film is made of the same material as the dam, and the dam is formed in the same step as the insulation film.

According to the foregoing arrangements, the dam and the insulation film are formed in the same step, so that it is possible to carry out a conventional step of forming a surface-mounted package without any change. Therefore, it is possible to suppress increase of the cost.

Further, it is preferable to arrange the semiconductor apparatus of the present embodiment so that the conductor section has a groove extending from the through hole to an outer edge of the conductor section.

Further, it is preferable to arrange the method of the present embodiment for manufacturing a semiconductor apparatus so that a groove extending from the through hole to an outer edge of the conductor section is formed after forming the through hole and before forming the joint terminal.

According to the foregoing arrangements, in melting the solder constituting the joint terminal so as to provide the joint terminal on the conductor section, the groove allows reduction of air included and kept in the solder. Thus, it is possible to finally suppress presence of voids in the joint terminal and improve the packaging reliability.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor apparatus, comprising:
a conductor section provided on a surface of a semiconductor chip so as to input and output an electric signal; and
a joint terminal provided on the surface of the conductor section so as to joint the conductor section to a package substrate, wherein
the conductor section has a level difference on its surface, and the joint terminal is provided along the level difference.

2. The semiconductor apparatus as set forth in claim 1, wherein a through hole which pierces a center of the surface of the conductor section is provided so as to form the level difference.

3. The semiconductor apparatus as set forth in claim 1, wherein a protrusion formed in a cylindrical shape so as to be covered by the joint terminal is provided in the center of the surface of the conductor section so as to form the level difference.

4. The semiconductor apparatus as set forth in claim 1, wherein a protrusion formed along the through hole piercing the center of the surface of the conductor section so as to protrude from the conductor section and so as to be covered by the joint terminal is provided so as to form the level difference.

5. The semiconductor apparatus as set forth in claim 1, wherein:
a protrusion formed in the center of the surface of the conductor section and formed in a dome shape so as to be covered by the joint terminal is provided, and
a dam surrounding the protrusion and formed so as to be covered by the joint terminal is provided,
so as to form the level difference.

6. The semiconductor apparatus as set forth in claim 1, comprising an insulation film with which the conductor section is coated.

7. The semiconductor apparatus as set forth in claim 2, comprising an insulation film with which the conductor section is coated.

8. The semiconductor apparatus as set forth in claim 3, comprising an insulation film with which the conductor section is coated.

9. The semiconductor apparatus as set forth in claim 3, wherein the protrusion is made of polymer material.

10. The semiconductor apparatus as set forth in claim 8, wherein:
the insulation film is made of the same material as the protrusion, and
the protrusion is formed in the same step as the insulation film.

11. The semiconductor apparatus as set forth in claim 4, comprising an insulation film with which the conductor section is coated.

12. The semiconductor apparatus as set forth in claim 4, wherein the protrusion is made of polymer material.

13. The semiconductor apparatus as set forth in claim 11, wherein:
the insulation film is made of the same material as the protrusion, and
the protrusion is formed in the same step as the insulation film.

14. The semiconductor apparatus as set forth in claim 5, comprising an insulation film with which the conductor section is coated.

15. The semiconductor apparatus as set forth in claim 5, wherein the protrusion is made of elastomer.

16. The semiconductor apparatus as set forth in claim 14, wherein:
the insulation film is made of the same material as the dam, and
the dam is formed in the same step as the insulation film.

17. The semiconductor apparatus as set forth in claim 2, wherein the conductor section has a groove extending from the through hole to an outer edge of the conductor section.

18. A method for manufacturing a semiconductor apparatus including: a conductor section provided on a surface of a semiconductor chip so as to input and output an electric signal; and a joint terminal provided on the surface of the conductor section so as to joint the conductor section to a package substrate,
said method comprising the steps of:
forming a level difference on the surface of the conductor section; and
forming the joint terminal along the level difference.

19. The method as set forth in claim 18, wherein a through hole which pierces a center of the surface of the conductor section is provided so as to form the level difference.

20. The method as set forth in claim 18, wherein a protrusion formed in a cylindrical shape so as to be covered by the joint terminal is provided in the center of the surface of the conductor section so as to form the level difference.

21. The method as set forth in claim 18, wherein a protrusion formed along the through hole piercing the center of the surface of the conductor section so as to protrude from the conductor section and so as to be covered by the joint terminal is provided so as to form the level difference.

22. The method as set forth in claim 18, comprising the steps of:
providing a dam formed in the center of the surface of the conductor section and formed in a circular shape so as to be covered by the joint terminal; and
providing a protrusion formed inside the dam and formed in a dome shape so as to be covered by the joint terminal,
wherein the steps are carried out so as to form the level difference.

23. The method as set forth in claim 18, wherein an exposed portion of the conductor section is coated with an insulation film.

24. The method as set forth in claim 19, wherein an exposed portion of the conductor section is coated with an insulation film.

25. The method as set forth in claim 20, wherein an exposed portion of the conductor section is coated with an insulation film.

26. The method as set forth in claim 25, wherein:
the insulation film is made of the same material as the protrusion, and
the protrusion is formed in the same step as the insulation film.

27. The method as set forth in claim 21, wherein an exposed portion of the conductor section is coated with an insulation film.

28. The method as set forth in claim 27, wherein:
the insulation film is made of the same material as the protrusion, and
the protrusion is formed in the same step as the insulation film.

29. The method as set forth in claim 22, wherein an exposed portion of the conductor section is coated with an insulation film.

30. The method as set forth in claim 29, wherein:
the insulation film is made of the same material as the dam, and
the dam is formed in the same step as the insulation film.

31. The method as set forth in claim 19, wherein a groove extending from the through hole to an outer edge of the conductor section is formed after forming the through hole and before forming the joint terminal.
